(19) United States
(12) Patent Application Publication
(10) Pub. No.: US 2025/0069998 A1
(43) Pub. Date: Feb. 27, 2025

(54) SEMICONDUCTOR DEVICE

(71) Applicant: Rohm Co., Ltd., Kyoto-shi (JP)

(72) Inventor: Takahiro KOTANI, Kyoto-shi (JP)

(21) Appl. No.: 18/946,486

(22) Filed: Nov. 13, 2024

Related U.S. Application Data
(63) Continuation of application No. PCT/JP2023/016926, filed on Apr. 28, 2023.

(30) Foreign Application Priority Data
May 19, 2022 (JP) 2022-082598

(51) Int. Cl. H01L 23/495; H01L 23/00; H01L 25/065; H02M 7/00; H02M 7/537

(52) U.S. Cl. CPC H01L 23/49575; H01L 23/49555; H01L 25/0655; H02M 7/003; H02M 7/537; H01L 24/48; H01L 24/49; H01L 2224/48137; H01L 2224/48175; H01L 2224/49112

(57) ABSTRACT

A semiconductor device includes a plurality of first switching parts, a first control element, at least one lead, a plurality of first connection members and a plurality of second connection members. Each first switching part includes a first switching element and a second switching element. In the plurality of first switching parts, the first switching element and the second switching element are electrically connected in parallel to each other and are of different types. The first switching element and the second switching element of each first switching part are disposed around the first control element as viewed in a thickness direction.

### TECHNICAL FIELD

The present disclosure relates to a semiconductor device.

### BACKGROUND ART

Conventionally, semiconductor devices including a switching element such as MOSFETs (Metal Oxide Semiconductor Field Effect Transistor) or IGBTs (Insulated Gate Bipolar Transistor) are known. For example, JP-A-2020-004893 discloses an example of the conventional semiconductor device. The semiconductor device disclosed in JP-A-2020-004893 is an intelligent power module (hereinafter referred to as an IPM) used for, for example, drive control of a motor.

### BRIEF DESCRIPTION OF THE DRAWINGS

FIG. 1 is a perspective view illustrating a semiconductor device according to a first embodiment.

FIG. 2 is a plan view illustrating the semiconductor device according to the first embodiment.

FIG. 3 is a plan view of FIG. 2, in which a sealing member is indicated as imaginary lines.

FIG. 4 is a partially enlarged view of FIG. 3.

FIG. 5 is a partially enlarged view of FIG. 3.

FIG. 6 is front view illustrating a semiconductor device according to a first embodiment.

FIG. 7 is a side view (a right-side view) illustrating a semiconductor device according to a first embodiment.

FIG. 8 is a sectional view taken along a line VIII-VIII of FIG. 3.

FIG. 9 is a sectional view taken along a line IX-IX of FIG. 3.

FIG. 10 is a sectional view taken along a line X-X of FIG. 3.

FIG. 11 is a sectional view taken along a line XI-XI of FIG. 3.

FIG. 12 is a view illustrating a circuit configuration example of the semiconductor device according to the first embodiment.

FIG. 13 is a plan view illustrating a semiconductor device according to a first variation of the first embodiment, in which a sealing member is indicated as imaginary lines.

FIG. 14 is a plan view illustrating a semiconductor device according to a second variation of the first embodiment, in which a sealing member is indicated as imaginary lines.

FIG. 15 is a plan view enlarging a relevant part of a semiconductor device according to a third variation of the first embodiment.

FIG. 16 is a plan view enlarging a relevant part of a semiconductor device according to a fourth variation of the first embodiment.

FIG. 17 is a plan view enlarging a relevant part of a semiconductor device according to a fifth variation of the first embodiment.

FIG. 18 is a plan view enlarging a relevant part of a semiconductor device according to a sixth variation of the first embodiment.

FIG. 19 is a plan view enlarging a relevant part of a semiconductor device according to a seventh variation of the first embodiment.

FIG. 20 is a plan view enlarging a relevant part of a semiconductor device according to an eighth variation of the first embodiment.

FIG. 21 is a plan view enlarging a relevant part of a semiconductor device according to an eighth variation of the first embodiment.

FIG. 22 is a plan view illustrating a semiconductor device according to a second embodiment, in which a sealing member is indicated as imaginary lines.

FIG. 23 is a sectional view taken along a line XXIII-XXIII of FIG. 22.

FIG. 24 is a sectional view taken along a line XXIV-XXIV of FIG. 22.

FIG. 25 is a plan view illustrating a semiconductor device according to a third embodiment, in which a sealing member is indicated as imaginary lines.

FIG. 26 is a partially enlarged view of FIG. 25.

FIG. 27 is a partially enlarged view of FIG. 25.

FIG. 28 is a plan view illustrating a semiconductor device according to a fourth embodiment, in which a sealing member is indicated as imaginary lines.

FIG. 29 is a partially enlarged view of FIG. 28.

FIG. 30 is a partially enlarged view of FIG. 28.

FIG. 31 is a view illustrating a circuit configuration example of the semiconductor device according to the fourth embodiment.

### DETAILED DESCRIPTION OF EMBODIMENTS

The following describes preferable mode for carrying out the semiconductor device of the present disclosure with reference to the accompanying drawings. In the following, the same reference numerals are given to the same or similar components, and redundant descriptions thereof are omitted. In the present disclosure, the terms “first,” “second,” “third,” etc. are used merely for the purpose of identification and are not necessarily intended to order their objects.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”.

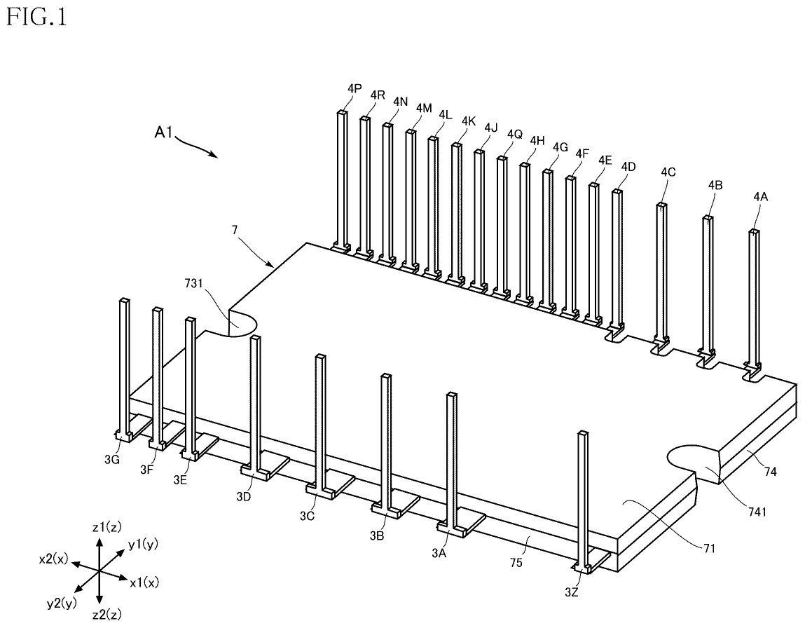

FIGS. 1-12 illustrate a semiconductor device A1 according to a first embodiment. The semiconductor device A1 includes a plurality of first switching parts 1, a plurality of second switching parts 2, a plurality of leads 3A-3G, 3Z, a plurality of leads 4A-4H, 4J-4N, 4P-4R, a support substrate 51, a plurality of connection members 6, a sealing member 7, a first control element 8A, a second control element 8B, and a plurality of electronic components 89U, 89V, 89W. The connection members 6 includes a plurality of wires 6A-6H, 6J-6L, 6Q. The application of the semiconductor device A1 is not limited, e.g. it is formed as an IPM used for a drive control of motors or the like.

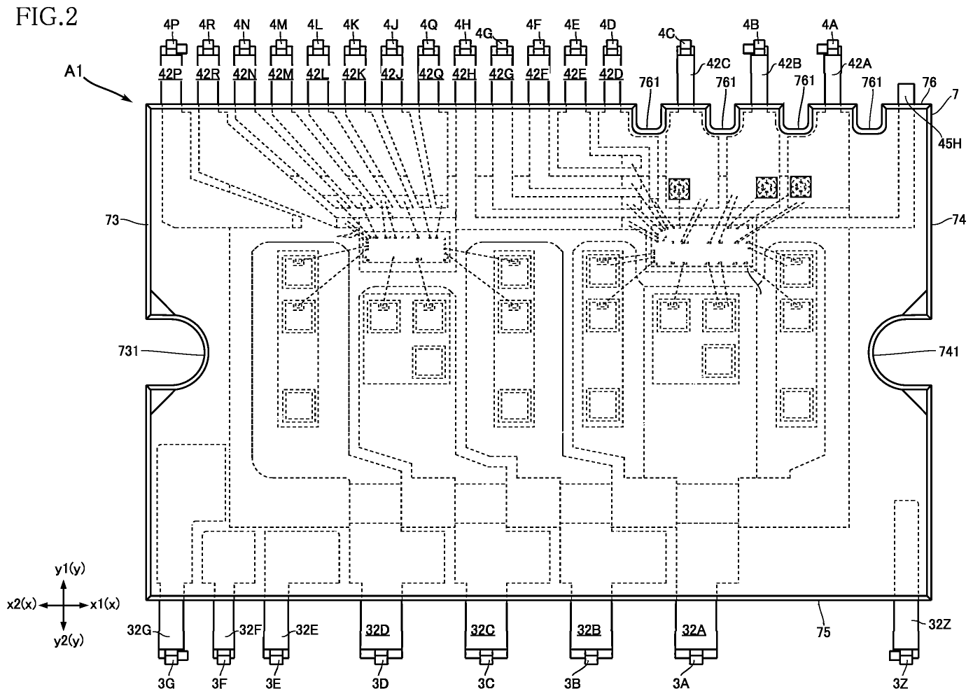

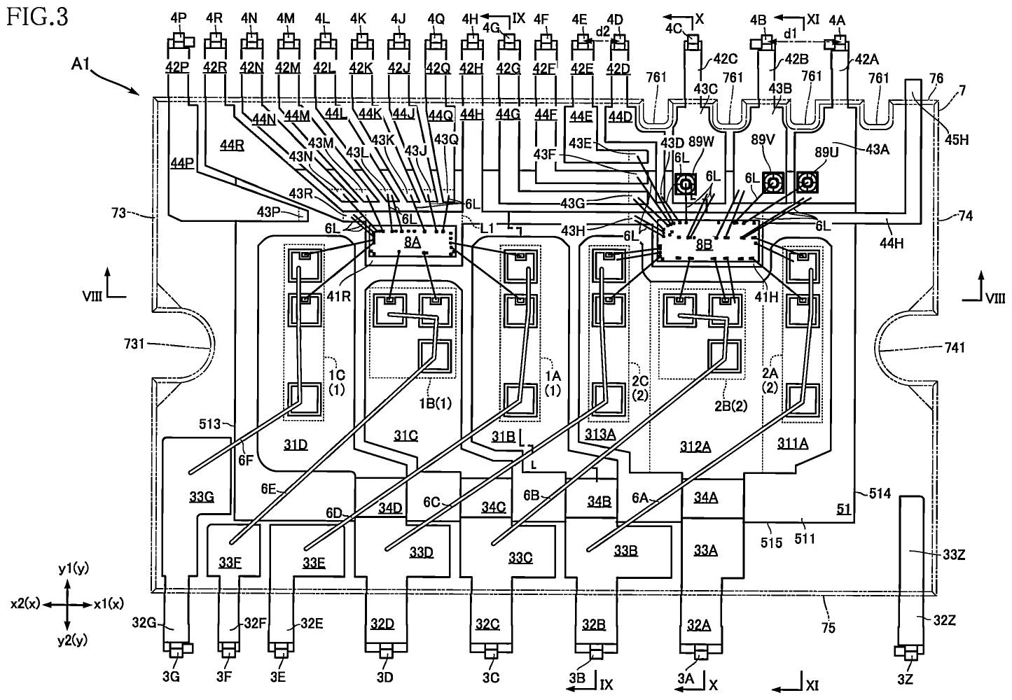

For convenience of explanation, three directions orthogonal to one another, namely an x direction, a y direction, and a z direction, will be referred to. The z direction corresponds to the thickness direction of the semiconductor device A1. In the description below, one side or sense in the thickness direction z may be referred to as “upward” or “upside”, and the other side or sense as “downward” or “downside”. Note that the terms such as “top”, “bottom”, “upward”, “downward”, “upper surface”, and “lower surface” are used to indicate the relative position between parts or the like, in the thickness direction z and do not necessarily define the relationship with respect to the direction of gravity. Also, “plan view” refers to the view seen in the thickness direction z. The x direction corresponds to the horizontal direction in plan views of the semiconductor device A1 (see FIGS. 2 and 3). The y direction corresponds to the vertical direction in plan views of the semiconductor device A1 (see FIGS. 2 and 3). In the present embodiment, the x direction is an example of a “first direction” and the y direction is an example of a “second direction”.

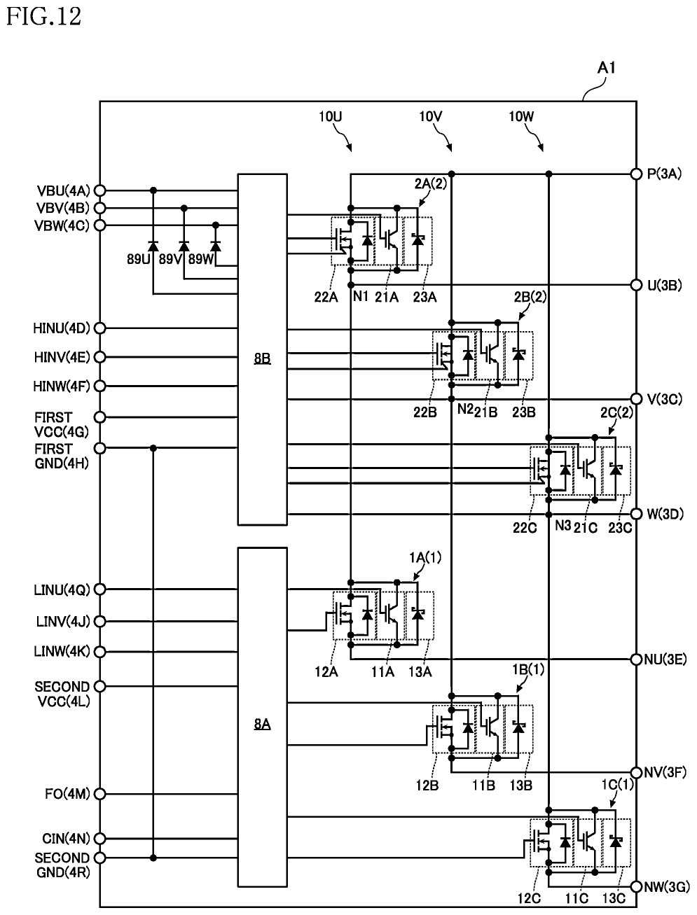

The first switching parts 1 and the second switching parts 2 serves to perform the electrical functions of the semiconductor device A1. In the semiconductor device A1, the first switching parts 1 and the second switching parts 2, as shown in FIG. 12, compose an inverter circuit for a three-phase AC current.

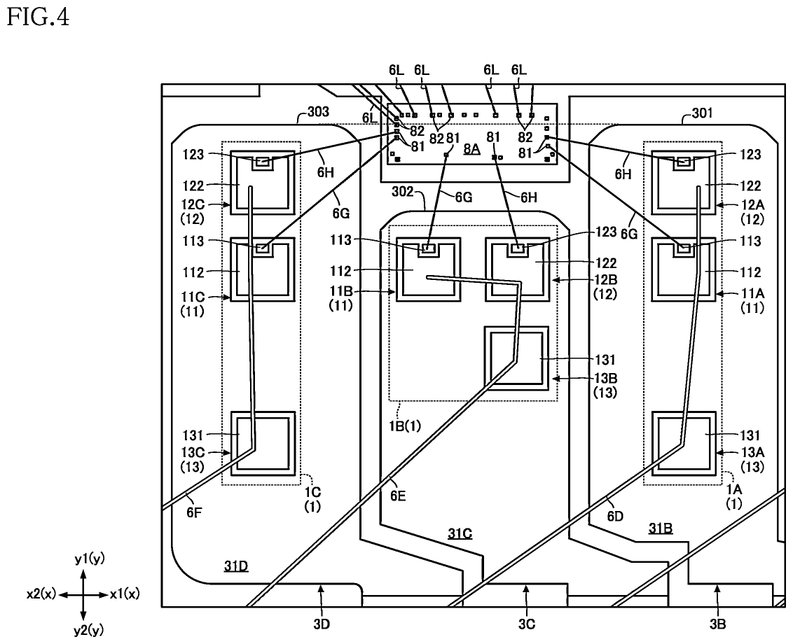

The first switching parts 1 include a first arm 1A, a second arm 1B and a third arm 1C, as shown in FIGS. 3, 4 and 12. The first arm 1A, the second arm 1B and the third arm 1C are arranged along the x direction, as shown in FIG. 4. The second arm 1B is located between the first arm 1A and the third arm 1C in the x direction. Each of the first switching parts 1 (the first arm 1A, the second arm 1B and the third arm 1C) switches between on and off states in response to a first drive signal from the first control element 8A.

Each of the first switching parts 1 (the first arm 1A, the second arm 1B and the third arm 1C) includes a first switching element 11, a second switching element 12 and a first protective element 13. For convenience of explanation, the first switching elements 11 of the first arm 1A, the second arm 1B and the third arm 1C is referred to as a first switching element 11A, a first switching element 11B and a first switching element 11C, respectively. Also, the second switching elements 12 of the first arm 1A, the second arm 1B and the third arm 1C is referred to as a second switching element 12A, a second switching element 12B and a second switching element 12C, respectively, and the first protective elements 13 of the first arm 1A, the second arm 1B and the third arm 1C is referred to as a first protective element 13A, a first protective element 13B and a first protective element 13C, respectively. In the description below, the first switching element 11, the second switching element 12 and the first protective element 13 are, unless otherwise specifically noted, common among the first switching parts 1 (each of the first arm 1A, the second arm 1B and the third arm 1C).

Each of the first switching element 11 and the second switching element 12 is a power semiconductor element. Each of the first switching element 11 and the second switching element 12 is, for example, one of an IGBT, a bipolar transistor, a MOSFET, a HEMT (High Electron Mobility Transistor) and the like. The first switching element 11 and the second switching element 12 are of different types. Types of switching elements in the present disclosure may be classified according to differences in structure such as an IGBT, a bipolar transistor, a MOSFET, and a HEMT. In the semiconductor device A1, the first switching element 11 is an IGBT and the second switching element 12 is a MOSFET, as shown in FIG. 12. Each of the first switching element 11 and the second switching element 12 contains semiconductor materials. The semiconductor material includes SiC (silicon carbide), Si (silicon), GaAs (gallium arsenide), GaN (gallium nitride) or the like. In the semiconductor device A1, the first switching element 11 contains Si as the semiconductor material and the second switching element 12 contains SiC as the semiconductor material.

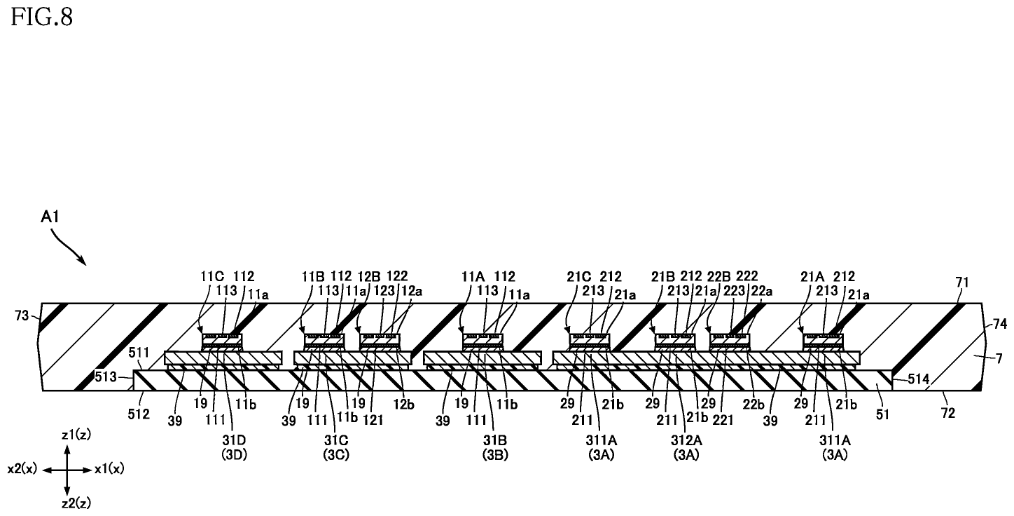

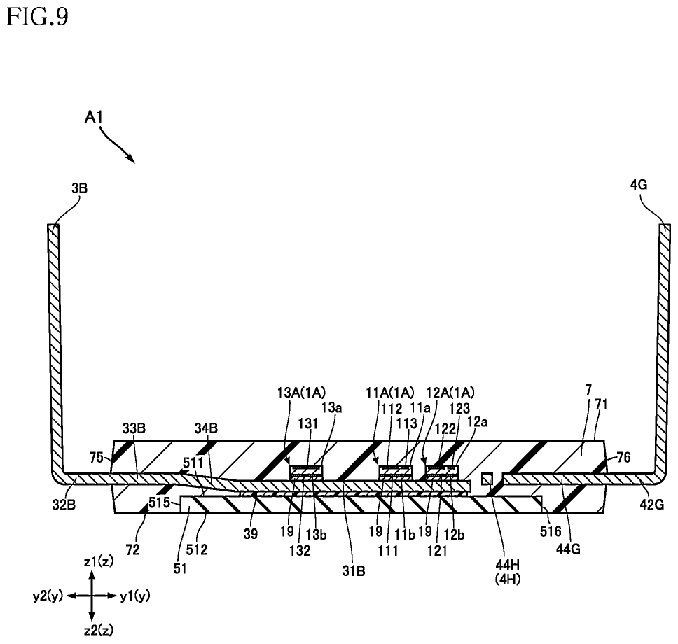

The first switching element 11 includes an element obverse surface 11a and an element reverse surface 11b, as shown in FIGS. 8 and 9. The element obverse surface 11a and the element reverse surface 11b are separated in the z direction. The element obverse surface 11a faces upward in the z direction (the z1 side of the z direction) and the element reverse surface 11b faces downward in the z direction (the z2 side of the z direction). Each of the element obverse surface 11a and the element reverse surface 11b is flat (or may be generally flat).

The first switching element 11 has three electrodes 111, 112, 113. The electrode 111 is provided on the element reverse surface 11b and the electrodes 112,113 are provided on the element obverse surface 11a. In the example where the first switching element 11 is an IGBT, the electrode 111 is a collector, the electrode 112 is an emitter, and the electrode 113 is a gate. The first switching element 11 performs switching operation in response to a drive signal input to the electrode 113 (a first drive signal). This switching operation means switching between the on state, in which current flows between the two electrodes 111, 112, and the off state, in which no current flows between the two electrodes 111, 112. When the first switching element 11 is in the on state, forward current flows from the electrode 111 to the electrode 112.

The second switching element 12 includes an element obverse surface 12a and an element reverse surface 12b, as shown in FIGS. 8 and 9. The element obverse surface 12a and the element reverse surface 12b are separated in the z direction. The element obverse surface 12a faces upward in the z direction (the z1 side of the z direction) and the element reverse surface 12b faces downward in the z direction (the z2 side of the z direction). Each of the element obverse surface 12a and the element reverse surface 12b is flat (or may be generally flat).

The second switching element 12 has three electrodes 121, 122, 123. The electrode 121 is provided on the element reverse surface 12b and the electrodes 122,123 are provided on the element obverse surface 12a. In the example where the second switching element 12 is a MOSFET, the electrode 121 is a drain, the electrode 122 is a source, and the electrode 123 is a gate. The second switching element 12 performs switching operation in response to a drive signal input to the electrode 123 (a first drive signal). This switching operation means switching between the on state, in which current flows between the two electrodes 121, 122, and the off state, in which no current flows between the two electrodes 121, 122. When the second switching element 12 is in the on state, forward current flows from the electrode 121 to the electrode 122.

In each first switching part 1 (each of the first arm 1A, the second arm 1B and the third arm 1C), the first switching element 11 and the second switching element 12 are electrically connected in parallel. Specifically, the electrode 111 (the collector) is electrically connected to the electrode 121 (the drain), and the electrode 112 (the emitter) is electrically connected to the electrode 122 (the source).

The first protective element 13 includes a diode function part. This diode function part serves as a free-wheeling diode. In the present embodiment, the first protective element 13 is, for example, a Schottky barrier diode, but it may be other types of diodes.

The first protective element 13 includes an element obverse surface 13a and an element reverse surface 13b, as shown in FIG. 9. The element obverse surface 13a and the element reverse surface 13b are separated in the z direction. The element obverse surface 13a faces upward in the z direction (the z1 side of the z direction) and the element reverse surface 13b faces downward in the z direction (the z2 side of the z direction). Each of the element obverse surface 13a and the element reverse surface 13b is flat (or may be generally flat).

The first protective element 13 has two electrodes 131, 132, as shown in FIG. 9. The electrode 131 is provided on the element obverse surface 13a and the electrode 132 is provided on the element reverse surface 13b. In the example where the first switching element 11 is a diode, the electrode 131 is an anode, the electrode 132 is a cathode.

In each first switching part 1 (each of the first arm 1A, the second arm 1B and the third arm 1C), the first protective element 13 is connected in anti-parallel to the first switching element 11 and the second switching element 12. Anti-parallel means a parallel connection where the forward current through each of the first switching element 11 and the second switching element 12 is opposite to the forward current through the first protective element 13. The electrode 131 (the anode) of the first protective element 13 is connected to the electrode 112 (the emitter) of the first switching element 11 and the electrode 122 (the source) of the second switching element 12, and the electrode 132 (the cathode) of the first protective element 13 is connected to the electrode 111 (the collector) of the first switching element 11 and the electrode 121 (the drain) of the second switching element 12. Hence, in each first switching part 1, when a reverse voltage is applied to the first switching element 11 and the second switching element 12, the forward current flows through the first protective element 13, so that the reverse voltage applied to the first switching element 11 and the second switching element 12 is reduced.

As understood from FIGS. 8 and 9, each of the first switching element 11A, the second switching element 12A and the first protective element 13A is bonded to the lead 3B via a conductive bonding material 19. Each of the first switching element 11B, the second switching element 12B and the first protective element 13B is bonded to the lead 3C via the conductive bonding material 19. Each of the first switching element 11C, the second switching element 12C and the first protective element 13C is bonded to the lead 3D via the conductive bonding material 19. Examples of these conductive bonding materials 19 include solder, metal paste material or sintered metal.

The first switching element 11A, the second switching element 12A and the first protective element 13A are arranged along the y direction, as shown in FIG. 4. The first switching element 11B and the second switching element 12B are arranged along the x direction. The first protective element 13B is offset in the y2 side of the y direction with respect to the second switching element 12B, and the second switching element 12B and the first protective element 13B are arranged along the y direction. The first switching element 11C, the second switching element 12C and the first protective element 13C are arranged along the y direction. The first switching elements 11A, 11B, 11C and the second switching elements 12A, 12B, 12C are disposed around the first control element 8A (located around the first control element 8A) in plan view, as shown in FIG. 4. In each first switching part 1 (each of the first arm 1A, the second arm 1B and the third arm 1C), the first switching element 11 and the second switching element 12 may be positioned inversely.

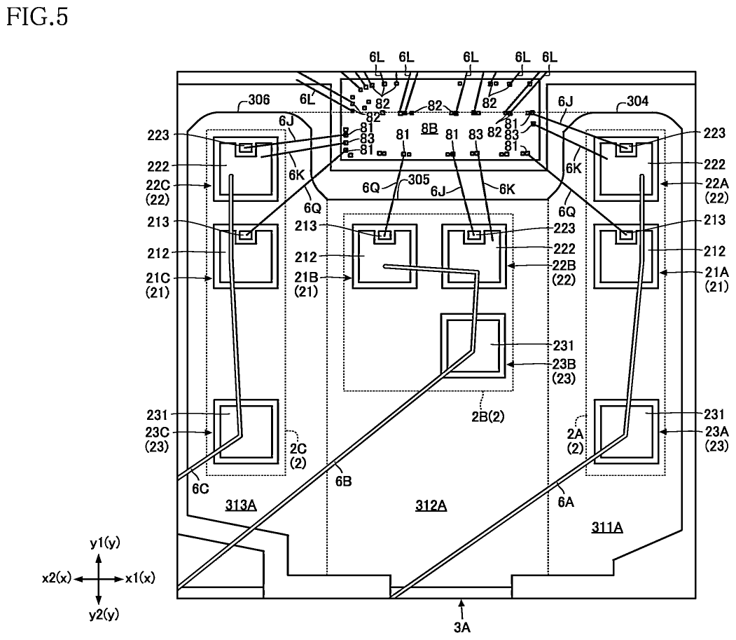

The second switching parts 2 include a fourth arm 2A, a fifth arm 2B and a sixth arm 2C. The fourth arm 2A, the fifth arm 2B and the sixth arm 2C are arranged along the x direction, as shown in FIG. 5. The fifth arm 2B is located between the fourth arm 2A and the sixth arm 2C in the x direction. Each of the second switching parts 2 (the fourth arm 2A, the fifth arm 2B and the sixth arm 2C) switches between on and off states in response to a second drive signal from the second control element 8B.

Each of the second switching parts 2 (the fourth arm 2A, the fifth arm 2B and the sixth arm 2C) includes a third switching element 21, a fourth switching element 22 and a second protective element 23. For convenience of explanation, the third switching elements 21 of the fourth arm 2A, the fifth arm 2B and the sixth arm 2C is referred to as a third switching element 21A, a third switching element 21B and a third switching element 21C, respectively. Also, the fourth switching elements 22 of the fourth arm 2A, the fifth arm 2B and the sixth arm 2C is referred to as a fourth switching element 22A, a fourth switching element 22B and a fourth switching element 22C, respectively, and the second protective elements 23 of the fourth arm 2A, the fifth arm 2B and the sixth arm 2C is referred to as a second protective element 23A, a second protective element 23B and a second protective element 23C, respectively. In the description below, the third switching element 21, the fourth switching element 22 and the second protective element 23 are, unless otherwise specifically noted, common among the second switching parts 2 (each of the fourth arm 2A, the fifth arm 2B and the sixth arm 2C).

Each of the third switching element 21 and the fourth switching element 22 is a power semiconductor element, as with the first switching element 11 and the second switching element 12. Each of the third switching element 21 and the fourth switching element 22 is, for example, one of an IGBT, a bipolar transistor, a MOSFET, a HEMT and the like. The third switching element 21 and the fourth switching element 22 are of different types. In the semiconductor device A1, the third switching element 21 is an IGBT and the fourth switching element 22 is a MOSFET, as shown in FIG. 12. Each of the third switching element 21 and the fourth switching element 22 contains semiconductor materials. The semiconductor material includes SiC (silicon carbide), Si (silicon), GaAs (gallium arsenide), GaN (gallium nitride) or the like. In the semiconductor device A1, the third switching element 21 contains Si as the semiconductor material and the fourth switching element 22 contains SiC as the semiconductor material.

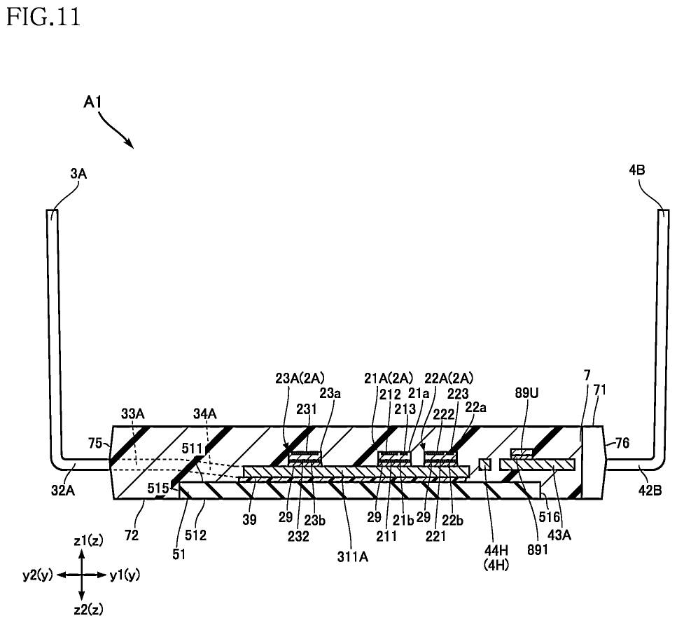

The third switching element 21 includes an element obverse surface 21a and an element reverse surface 21b, as shown in FIG. 11. The element obverse surface 21a and the element reverse surface 21b are separated in the z direction. The element obverse surface 21a faces upward in the z direction (the z1 side of the z direction) and the element reverse surface 21b faces downward in the z direction (the z2 side of the z direction). Each of the element obverse surface 21a and the element reverse surface 21b is flat (or may be generally flat).

The third switching element 21 has three electrodes 211, 212, 213. The electrode 211 is provided on the element reverse surface 21b and the electrodes 212,213 are provided on the element obverse surface 21a. In the example where the third switching element 21 is an IGBT, the electrode 211 is a collector, the electrode 212 is an emitter, and the electrode 213 is a gate. The third switching element 21 performs switching operation in response to a drive signal input to the electrode 213 (a second drive signal). This switching operation means switching between the on state, in which current flows between the two electrodes 211, 212, and the off state, in which no current flows between the two electrodes 211, 212. When the third switching element 21 is in the on state, forward current flows from the electrode 211 to the electrode 212.

The fourth switching element 22 includes an element obverse surface 22a and an element reverse surface 22b, as shown in FIG. 11. The element obverse surface 22a and the element reverse surface 22b are separated in the z direction. The element obverse surface 22a faces upward in the z direction (the z1 side of the z direction) and the element reverse surface 22b faces downward in the z direction (the z2 side of the z direction). Each of the element obverse surface 22a and the element reverse surface 22b is flat (or may be generally flat).

The fourth switching element 22 has three electrodes 221, 222, 223. The electrode 221 is provided on the element reverse surface 22b and the electrodes 222,223 are provided on the element obverse surface 22a. In the example where the fourth switching element 22 is a MOSFET, the electrode 221 is a drain, the electrode 222 is a source, and the electrode 223 is a gate. The fourth switching element 22 performs switching operation in response to a drive signal input to the electrode 223 (a second drive signal). This switching operation means switching between the on state, in which current flows between the two electrodes 221, 222, and the off state, in which no current flows between the two electrodes 221, 222. When the fourth switching element 22 is in the on state, forward current flows from the electrode 221 to the electrode 222.

In each second switching part 2 (each of the fourth arm 2A, the fifth arm 2B and the sixth arm 2C), the third switching element 21 and the fourth switching element 22 are electrically connected in parallel. Specifically, the electrode 211 (the collector) is electrically connected to the electrode 221 (the drain) and the electrode 212 (the emitter) is electrically connected to the electrode 222 (the source).

The second protective element 23 includes a diode function part. This diode function part serves as a free-wheeling diode. In the present embodiment, the second protective element 23 is, for example, a Schottky barrier diode.

The second protective element 23 includes an element obverse surface 23a and an element reverse surface 23b, as shown in FIG. 11. The element obverse surface 23a and the element reverse surface 23b are separated in the z direction. The element obverse surface 23a faces upward in the z direction (the z1 side of the z direction) and the element reverse surface 23b faces downward in the z direction (the z2 side of the z direction). Each of the element obverse surface 23a and the element reverse surface 23b is flat (or may be generally flat).

The second protective element 23 has two electrodes 231, 232, as shown in FIG. 11. The electrode 231 is provided on the element obverse surface 23a and the electrode 232 is provided on the element reverse surface 23b. In the example where the third switching element 21 is a diode, the electrode 231 is an anode, the electrode 232 is a cathode.

In each second switching part 2 (each of the fourth arm 2A, the fifth arm 2B and the sixth arm 2C), the second protective element 23 is connected in anti-parallel to the third switching element 21 and the fourth switching element 22. Anti-parallel means a parallel connection where the forward current through each of the third switching element 21 and the fourth switching element 22 is opposite to the forward current through the second protective element 23. The electrode 231 (the anode) of the second protective element 23 is connected to the electrode 212 (the emitter) of the third switching element 21 and the electrode 222 (the source) of the fourth switching element 22, and the electrode 232 (the cathode) of the second protective element 23 is connected to the electrode 211 (the collector) of the third switching element 21 and the electrode 221 (the drain) of the fourth switching element 22. Hence, in each second switching part 2, when a reverse voltage is applied to the third switching element 21 and the fourth switching element 22, the forward current flows through the second protective element 23, so that the reverse voltage applied to the third switching element 21 and the fourth switching element 22 is reduced.

As understood from FIGS. 8 and 11, each of the third switching element 21A, the fourth switching element 22A and the second protective element 23A is bonded to the lead 3A via a conductive bonding material 29. Each of the third switching element 21B, the fourth switching element 22B and the second protective element 23B is also bonded to the lead 3A via the conductive bonding material 29. Each of the third switching element 21C, the fourth switching element 22C and the second protective element 23C is also bonded to the lead 3A via the conductive bonding material 29. These conductive bonding materials 29 include solder, metal paste material or sintered metal.

The third switching element 21A, the fourth switching element 22A and the second protective element 23A are arranged along the y direction, as shown in FIG. 5. The third switching element 21B and the fourth switching element 22B are arranged along the x direction. The second protective element 23B is offset in the y2 side of the y direction with respect to the fourth switching element 22B, and the fourth switching element 22B and the second protective element 23B are arranged along the y direction. The third switching element 21C, the fourth switching element 22C and the second protective element 23C are arranged along the y direction. The third switching elements 21A, 21B, 21C and the fourth switching elements 22A, 22B, 22C are disposed around the second control element 8B in plan view, as shown in FIG. 5. In each second switching part 2 (each of the fourth arm 2A, the fifth arm 2B and the sixth arm 2C), the third switching element 21 and the fourth switching element 22 may be positioned inversely.

As shown in FIG. 12, the inverter circuit for a three-phase AC current, which is composed of the first switching parts 1 and the second switching parts 2, includes a first phase 10U, a second phase 10V and a third phase 10W. The first phase 10U, the second phase 10V and the third phase 10W correspond to a U phase, a V phase and a W phase, respectively.

The first phase 10U includes the first arm 1A and the fourth arm 2A. In the first phase 10U, the first arm 1A and the fourth arm 2A are electrically connected in series. The first arm 1A is a lower arm of the first phase 10U and the fourth arm 2A is an upper arm of the first phase 10U.

The second phase 10V includes the second arm 1B and the fifth arm 2B. In the second phase 10V, the second arm 1B and the fifth arm 2B are electrically connected in series. The second arm 1B is a lower arm of the second phase 10V and the fifth arm 2B is an upper arm of the second phase 10V.

The third phase 10W includes the third arm 1C and the sixth arm 2C. In the third phase 10W, the third arm 1C and the sixth arm 2C are electrically connected in series. The third arm 1C is a lower arm of the third phase 10W and the sixth arm 2C is an upper arm of the third phase 10W.

The first control element 8A controls the switching operations of the first switching elements 11 and the second switching elements 12 and is, for example, a driver IC. The first control element 8A receives a first input signal from external sources and generates a first drive signal to control the switching operation of each first switching part 1 depending on the first input signal. The first control element 8A outputs the first drive signal (e.g. a gate voltage) to the electrode 113 (the gate) of each first switching element 11 and the electrode 123 (the gate) of each second switching element 12. Consequently, the switching operations of each first switching element 11 and each second switching element 12 are controlled. In the present embodiment, the first control element 8A has a rectangular shape with the x direction as the longitudinal direction in plan view.

In the present embodiment, the first control element 8A provides the first drive signal input to the first switching element 11 and the first drive signal input to the second switching elements 12 with a delay time to each first switching part 1 (each of the first arm 1A, the second arm 1B and the third arm 1C). The delay time is preferably designed, for example, depending on a switching speed of the first switching element 11 and a switching speed of the second switching element 12. In an example where the first switching element 11 is an IGBT and the second switching element 12 is a MOSFET, the first drive signal to the second switching elements 12 switches from the on signal to the off signal and from the off signal to the on signal earlier than the first drive signal to the first switching element 11. However, it may not be necessary for the first control element 8A to provide the delay time between the first drive signal input to the first switching element 11 and the first drive signal input to the second switching elements 12.

The second control element 8B controls the switching operations of the third switching elements 21 and the fourth switching elements 22 and is, for example, a driver IC. The second control element 8B receives a second input signal from external sources and generates a second drive signal to control the switching operation of each second switching part 2 depending on the second input signal. The second control element 8B outputs the second drive signal (e.g. a gate voltage) to the electrode 213 (the gate) of each third switching element 21 and the electrode 223 (the gate) of each fourth switching element 22. Consequently, the switching operations of each third switching element 21 and each fourth switching element 22 are controlled. In the present embodiment, the second control element 8B has a rectangular shape with the x direction as the longitudinal direction in plan view.

In the present embodiment, the second control element 8B provides the second drive signal input to the third switching element 21 and the second drive signal input to the fourth switching elements 22 with a delay time to each second switching part 2 (each of the fourth arm 2A, the fifth arm 2B and the sixth arm 2C). The delay time is preferably designed, for example, depending on a switching speed of the third switching element 21 and a switching speed of the fourth switching element 22. In an example where the third switching element 21 is an IGBT and the fourth switching element 22 is a MOSFET, the second drive signal to the fourth switching elements 22 switches from the on signal to the off signal and from the off signal to the on signal earlier than the second drive signal to the third switching element 21. However, it may not be necessary for the second control element 8B to provide the delay time between the second drive signal input to the third switching element 21 and the second drive signal input to the fourth switching elements 22.

Each of the first control element 8A and the second control element 8B has a plurality of electrodes 81, 82. The electrodes 81, 82 are disposed on the upper surface of each of the first control element 8A and the second control element 8B. The electrodes 81 of the first control element 8A is electrically connected to one of the first switching parts 1 (the first arm 1A, the second arm 1B and the third arm 1C). The above-described first drive signal is output from the electrodes 81 of the first control element 8A. The electrodes 82 of the first control element 8A are electrically connected to one of the leads 4A-4H. The electrodes 81 of the second control element 8B are electrically connected to one of the second switching parts 2 (the fourth arm 2A, the fifth arm 2B and the sixth arm 2C). The above-described second drive signal is output from the electrodes 81 of the second control element 8B. The electrodes 82 of the second control element 8B is electrically connected to one of the leads 4J-4N, 4Q, 4R. Further, the second control element 8B has a plurality of electrodes 83. The electrodes 83 are disposed on the upper surface of each second control element 8B. Each of the electrodes 83 of the second control element 8B are electrically connected to relevant one of the second switching parts 2 (the fourth arm 2A, the fifth arm 2B and the sixth arm 2C). A detection signal is input to the electrodes 83 for detecting the conduction state of each first switching part 1.

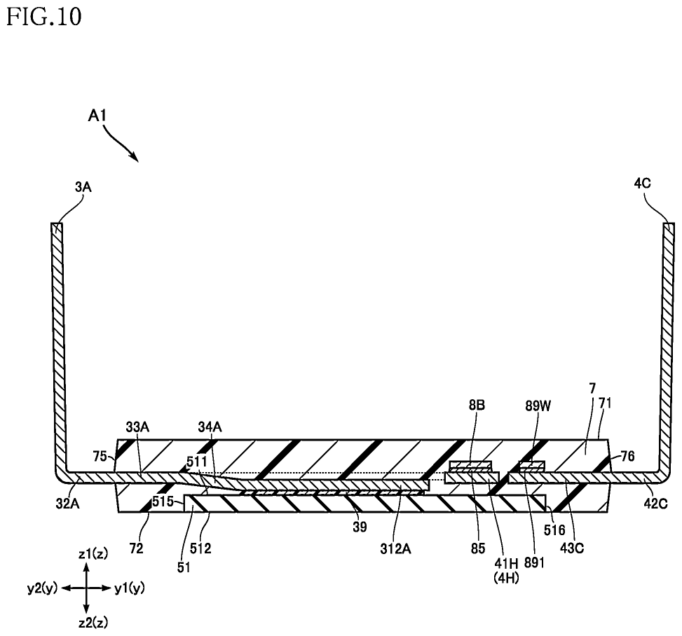

The first control element 8A is bonded to the lead 4R via a bonding material 85, and the second control element 8B is, as shown in FIG. 10, bonded to the lead 4H via a bonding material 85. Since the semiconductor device A1 has no electrodes on the lower surface (the surface facing the z2 side of the z direction) of each of the first control element 8A and the second control element 8B, the bonding material 85 may be either conductive or insulating. However, in the case where electrodes are provided on the lower surface of each of the first control element 8A and the second control element 8B, the bonding material 85 may be composed of a conductive one (e.g. solder, metal paste material or sintered metal).

Each of the electronic components 89U, 89V, 89W supplements the function of each of the first control element 8A and the second control element 8B and is, for example, a diode. The example illustrated in FIG. 3 includes three electronic components 89U, 89V, 89W, but the number of electronic components is not limited to this. The electronic components 89U, 89V, 89W are each bonded to a relevant one of the leads 4A, 4B, 4C, as shown in FIG. 3. Each of the electronic components 89U, 89V, 89W is bonded by a conductive bonding material 891, as shown in FIG. 11. The conductive bonding material 891 includes solder, metal paste material, sintered metal or the like.

As shown in FIG. 3, the leads 3A-3G, 3Z and the leads 4A-4H, 4J-4N, 4P-4R support the first switching elements 11, the second switching elements 12, the first protective elements 13, the third switching elements 21, the fourth switching elements 22, the second protective elements 23, the first control element 8A, the second control element 8B, and the electronic components 89U, 89V, 89W, and constitute conduction paths to them. Among the leads 3A-3G, 3Z and the leads 4A-4H, 4J-4N, 4P-4R, the lead 4H and the lead 4R integrally formed, while the others are separated from each other. An auxiliary line Li in FIG. 3 indicates the boundary between the lead 4H and the lead 4R, which corresponds to an integrally connected portion. Note that the lead 4H and the lead 4R may be viewed as a single lead. Unlike this example, the lead 4H and the lead 4R may be separated from each other.

The leads 3A-3G, 3Z and the leads 4A-4H, 4J-4N, 4P-4R may be made of different conductive members from each other or one conductive member. The leads 3A-3G, 3Z and the leads 4A-4H, 4J-4N, 4P-4R are made of Cu or a Cu alloy, for example. Each of the leads 3A-3G, 3Z and the leads 4A-4H, 4J-4N, 4P-4R may be made of Ni, a Ni alloy or 42 alloy instead of Cu or a Cu alloy. Note that Each of the leads 3A-3G, 3Z and the leads 4A-4H, 4J-4N, 4P-4R may be made of the same material or different materials.

In the case where the semiconductor device A1 is configured as an IPM, a motor drive current flows through the leads 3A-3G and a control current flows through the leads 4A-4H, 4J-4N, 4P-4R. Hence, the leads 3A-3G is subjected to a higher voltage and a greater current than the leads 4A-4H, 4J-4N, 4P-4R. In the present embodiment, the leads 3A-3G, 3Z on the high-voltage side and the leads 4A-4H, 4J-4N, 4P-4R on the low-voltage side are, as shown in FIG. 3, separated from each other on opposite sides in the y direction.

On the lead 3A, the third switching element 21, the fourth switching element 22 and the second protective element 23 of each second switching part 2 (the fourth arm 2A, the fifth arm 2B, and the sixth arm 2C) are mounted. The lead 3A, as understood from the later explained configuration, is electrically connected to the electrode 211 (the collector) of each third switching element 21, the electrode 221 (the drain) of each fourth switching element 22, and the electrode 232 (the cathode) of each second protective element 23. The lead 3A includes a plurality of mounting parts 311A, 312A, 313A, a terminal part 32A, a pad part 33A and a connection part 34A, as shown in FIGS. 3 and 5.

The mounting parts 311A, 312A, 313A are each covered by the sealing member 7, as shown in FIG. 3. The mounting parts 311A, 312A, 313A are integrally formed. Each of the mounting parts 311A, 312A, 313A is bonded to the support substrate 51 via a bonding material 39. The bonding material 39 may be conductive or insulative. It is preferably for the bonding material 39 to have high thermal conductivity.

On the mounting part 311A, the third switching element 21A, the fourth switching element 22A and the second protective element 23A are each mounted, as shown in FIG. 5. The mounting part 311A is electrically connected to the electrode 211 (the collector) of the third switching element 21A, the electrode 221 (the drain) of the fourth switching element 22A, and the electrode 232 (the cathode) of the second protective element 23A. In other words, the electrode 211 of the third switching element 21A, the electrode 221 of the fourth switching element 22A and the electrode 232 of the second protective element 23A are electrically connected to each other via the mounting part 311A.

On the mounting part 312A, the third switching element 21B, the fourth switching element 22B and the second protective element 23B are each mounted, as shown in FIG. 5. The mounting part 312A is electrically connected to the electrode 211 (the collector) of the third switching element 21B, the electrode 221 (the drain) of the fourth switching element 22B, and the electrode 232 (the cathode) of the second protective element 23B. In other words, the electrode 211 of the third switching element 21B, the electrode 221 of the fourth switching element 22B and the electrode 232 of the second protective element 23B are electrically connected to each other via the mounting part 312A.

On the mounting part 313A, the third switching element 21C, the fourth switching element 22C and the second protective element 23C are each mounted, as shown in FIG. 5. The mounting part 313A is electrically connected to the electrode 211 (the collector) of the third switching element 21C, the electrode 221 (the drain) of the fourth switching element 22C, and the electrode 232 (the cathode) of the second protective element 23C. In other words, the electrode 211 of the third switching element 21C, the electrode 221 of the fourth switching element 22C and the electrode 232 of the second protective element 23C are electrically connected to each other via the mounting part 313A.

The mounting parts 311A, 312A, 313A have following relationships, as shown in FIG. 5. An edge 304 of the mounting part 311A in the y1 side of the y direction and an edge 306 of the mounting part 313A in the y1 side of the y direction are in the same (or generally same) position in the y direction. Further, an edge 305 of the mounting part 312A in the y1 side of the y direction is in the y2 side of the y direction with respect to the aforementioned edges 304, 306. Hence, the mounting part 312A is, as shown in FIG. 5, arranged to be offset downward to the two mounting parts 311A, 313A in plan view, so that the mounting parts 311A, 312A, 313A as a whole are provided in a U-shape in plan view as a whole.

The terminal part 32A is a part of the lead 3A protruding from the sealing member 7, as shown in FIG. 3. In the y direction, the terminal part 32A protrudes in the opposite side to the leads 4A-4H, 4J-4N, 4P-4R with respect to each mounting part 311A, 312A, 313A. The terminal part 32A is provided to connect the semiconductor device A1 to an external circuit. In the illustrated example, the terminal part 32A has an L-shape with a bend in the z1 side of the z direction.

The pad part 33A and the connection part 34A are covered by the sealing member 7. The pad part 33A and the connection part 34A are interposed between the mounting part 312A and the terminal part 32A, as shown in FIG. 3. The pad part 33A is offset in the z1 side of the z direction with respect to the mounting part 312A and is connected to the terminal part 32A. As shown in FIG. 10, the connection part 34A is connected to the mounting part 311A and the pad part 33A, and is inclined with respect to the y direction.

The lead 3B, the lead 3C and the lead 3D are disposed in the x2 side of the x direction relative to the lead 3A, as shown in FIG. 3. The lead 3B, the lead 3C and the lead 3D are arranged along the x direction. In the illustrated example, the lead 3B and the lead 3D have the same (or generally same) shape and the same (or generally same) size.

On the lead 3B, the first arm 1A is mounted. More specifically, on the lead 3B, the first switching element 11A, the second switching element 12A and the first protective element 13A are each mounted. The lead 3B, as understood from the later explained configuration, is electrically connected to the electrode 111 (the collector) of the first switching element 11A, the electrode 121 (the drain) of the second switching element 12A, and the electrode 132 (the cathode) of the first protective element 13A. The lead 3B includes a mounting part 31B, a terminal part 32B, a pad part 33B and a connection part 34B, as shown in FIGS. 3 and 4.

The mounting part 31B is covered by the sealing member 7, as shown in FIG. 3. The mounting part 31B is bonded to the support substrate 51 via the bonding material 39. On the mounting part 31B, the first switching element 11A, the second switching element 12A and the first protective element 13A are each mounted, as shown in FIG. 4. The mounting part 31B is electrically connected to the electrode 111 (the collector) of the first switching element 11A, the electrode 121 (the drain) of the second switching element 12A, and the electrode 132 (the cathode) of the first protective element 13A. In other words, the electrode 111 of the first switching element 11A, the electrode 121 of the second switching element 12A, and the electrode 132 of the first protective element 13A are electrically connected to each other via the mounting part 31B.

The terminal part 32B is a part of the lead 3B protruding from the sealing member 7, as shown in FIG. 3. In the y direction, the terminal part 32B protrudes in the opposite side to the leads 4A-4H, 4J-4N, 4P-4R with respect to the mounting part 31B. The terminal part 32B is provided to connect the semiconductor device A1 to an external circuit. In the illustrated example, the terminal part 32B has an L-shape with a bend in the z1 side of the z direction.

The pad part 33B and the connection part 34B are covered by the sealing member 7. The pad part 33B and the connection part 34B are interposed between the mounting part 31B and the terminal part 32B, as shown in FIG. 3. The pad part 33B is offset in the z1 side of the z direction with respect to the mounting part 31B, as with the pad part 33A. The pad part 33B is connected to the terminal part 32B. A wire 6A is bonded to the pad part 33B. The connection part 34B is connected to the mounting part 31B and the pad part 33B, and is inclined with respect to the y direction, as with the connection part 34A.

On the lead 3C, the second arm 1B is mounted. More specifically, on the lead 3C, the first switching element 11B, the second switching element 12B and the first protective element 13B are each mounted. The lead 3C, as understood from the later explained configuration, is electrically connected to the electrode 111 (the collector) of the first switching element 11B, the electrode 121 (the drain) of the second switching element 12B, and the electrode 132 (the cathode) of the first protective element 13B. The lead 3C includes a mounting part 31C, a terminal part 32C, a pad part 33C and a connection part 34C, as shown in FIGS. 3 and 4.

The mounting part 31C is covered by the sealing member 7, as shown in FIG. 3. The mounting part 31C is bonded to the support substrate 51 via the bonding material 39. On the mounting part 31C, the first switching element 11B, the second switching element 12B and the first protective element 13B are each mounted, as shown in FIG. 4. The mounting part 31C is electrically connected to the electrode 111 (the collector) of the first switching element 11B, the electrode 121 (the drain) of the second switching element 12B, and the electrode 132 (the cathode) of the first protective element 13B. In other words, the electrode 111 of the first switching element 11B, the electrode 121 of the second switching element 12B, and the electrode 132 of the first protective element 13B are electrically connected to each other via the mounting part 31C.

The terminal part 32C is a part of the lead 3C protruding from the sealing member 7, as shown in FIG. 3. In the y direction, the terminal part 32C protrudes in the opposite side to the leads 4A-4H, 4J-4N, 4P-4R with respect to the mounting part 31C. The terminal part 32C is provided to connect the semiconductor device A1 to an external circuit. In the illustrated example, the terminal part 32C has an L-shape with a bend in the z1 side of the z direction.

The pad part 33C and the connection part 34C are covered by the sealing member 7. The pad part 33C and the connection part 34C are interposed between the mounting part 31C and the terminal part 32C, as shown in FIG. 3. The pad part 33C is offset in the z1 side of the z direction with respect to the mounting part 31C, as with the pad parts 33A, 33B. The pad part 33C is connected to the terminal part 32C. A wire 6B is bonded to the pad part 33C. The connection part 34C is connected to the mounting part 31C and the pad part 33C, and is inclined with respect to the y direction, as with the connection parts 34A, 34B.

On the lead 3D, the third arm 1C is mounted. More specifically, on the lead 3D, the first switching element 11C, the second switching element 12C and the first protective element 13C are each mounted. The lead 3D, as understood from the later explained configuration, is electrically connected to the electrode 111 (the collector) of the first switching element 11C, the electrode 121 (the drain) of the second switching element 12C, and the electrode 132 (the cathode) of the first protective element 13C. The lead 3D includes a mounting part 31D, a terminal part 32D, a pad part 33D and a connection part 34D, as shown in FIGS. 3 and 4.

The mounting part 31D is covered by the sealing member 7, as shown in FIG. 3. The mounting part 31D is bonded to the support substrate 51 via the bonding material 39. On the mounting part 31D, the first switching element 11C, the second switching element 12C and the first protective element 13C are mounted, as shown in FIG. 4. The mounting part 31D is electrically connected to the electrode 111 (the collector) of the first switching element 11C, the electrode 121 (the drain) of the second switching element 12C, and the electrode 132 (the cathode) of the first protective element 13C. In other words, the electrode 111 of the first switching element 11C, the electrode 121 of the second switching element 12C, and the electrode 132 of the first protective element 13C are electrically connected to each other via the mounting part 31D.

The terminal part 32D is a part of the lead 3D protruding from the sealing member 7, as shown in FIG. 3. In the y direction, the terminal part 32D protrudes in the opposite side to the leads 4A-4H, 4J-4N, 4P-4R with respect to the mounting part 31D. The terminal part 32D is provided to connect the semiconductor device A1 to an external circuit. In the illustrated example, the terminal part 32D has an L-shape with a bend in the z1 side of the z direction.

The pad part 33D and the connection part 34D are covered by the sealing member 7. The pad part 33D and the connection part 34D are interposed between the mounting part 31D and the terminal part 32D, as shown in FIG. 3. The pad part 33D is offset in the z1 side of the z direction with respect to the mounting part 31D, as with the pad parts 33A, 33B, 33C. The pad part 33D is connected to the terminal part 32D. A wire 6C is bonded to the pad part 33D. The connection part 34D is connected to the mounting part 31D and the pad part 33D, and is inclined with respect to the y direction, as with the connection parts 34A, 34B, 34C.

The mounting parts 31B, 31C, 31D have following relationships, as shown in FIG. 4. An edge 301 of the mounting part 31B in the y1 side of the y direction and an edge 303 of the mounting part 31D in the y1 side of the y direction are in the same (or generally same) position in the y direction. Further, an edge 302 of the mounting part 31C in the y1 side of the y direction is in the y2 side of the y direction with respect to the aforementioned edges 301, 303. Hence, the mounting part 31C is arranged to be offset downward to the two mounting parts 31B, 31D in plan view, as shown in FIG. 4.

The lead 3E, the lead 3F, and the lead 3G are disposed in the x2 side of the x direction with respect to the lead 3D, as shown in FIGS. 2 and 3. The lead 3E, the lead 3F, and the lead 3G are arranged along the x direction. None of the first switching parts 1 and the second switching parts 2 are mounted on each of the lead 3E, the lead 3F, and the lead 3G.

The lead 3E is electrically connected to the electrode 112 (the emitter) of the first switching element 11A, the electrode 122 (the source) of the second switching element 12A, and the electrode 131 (the anode) of the first protective element 13A by the later explained configuration. The lead 3E includes a terminal part 32E and a pad part 33E, as shown in FIG. 3. The terminal part 32E and the pad part 33E are connected to each other.

The terminal part 32E is a part of the lead 3E protruding from the sealing member 7. In the y direction, the terminal part 32E protrudes in the opposite side to the leads 4A-4H, 4J-4N, 4P-4R with respect to the pad part 33E, as shown in FIG. 3. The terminal part 32E is provided to connect the semiconductor device A1 to an external circuit. In the illustrated example, the terminal part 32E has an L-shape with a bend in the z1 side of the z direction.

The pad part 33E is covered by the sealing member 7, and is, in the illustrated example, rectangular in plan view. As shown in FIG. 3, the pad part 33E does not overlap with the support substrate 51 in plan view. The pad part 33E is disposed in the same position (the same height) as each of the pad parts 33A-33D in the z direction. As illustrated in FIG. 3, the pad part 33E is bonded to a wire 6D and electrically connect to the electrode 112 (the emitter) of the first switching element 11A, the electrode 122 (the source) of the second switching element 12A, and the electrode 131 (the anode) of the first protective element 13A via the wire 6D.

The lead 3F, as understood from the later explained configuration, is electrically connected to the electrode 112 (the emitter) of the first switching element 11B, the electrode 122 (the source) of the second switching element 12B, and the electrode 131 (the anode) of the first protective element 13B. The lead 3F includes a terminal part 32F and a pad part 33F, as shown in FIG. 3. The terminal part 32F and the pad part 33F are connected to each other.

The terminal part 32F is a part of the lead 3F protruding from the sealing member 7. In the y direction, the terminal part 32F protrudes in the opposite side to the leads 4A-4H, 4J-4N, 4P-4R with respect to the pad part 33F, as shown in FIG. 3. The terminal part 32F is provided to connect the semiconductor device A1 to an external circuit. In the illustrated example, the terminal part 32F has an L-shape with a bend in the z1 side of the z direction.

The pad part 33F is covered by the sealing member 7, and is, in the illustrated example, rectangular in plan view. As shown in FIG. 3, the pad part 33F does not overlap with the support substrate 51 in plan view. The pad part 33F is disposed in the same position (the same height) as each of the pad parts 33A-33E in the z direction. As shown in FIG. 3, the pad part 33F is bonded to a wire 6E and electrically connect to the electrode 112 (the emitter) of the first switching element 11B, the electrode 122 (the source) of the second switching element 12B, and the electrode 131 (the anode) of the first protective element 13B via the wire 6E.

The lead 3G, as understood from the later explained configuration, is electrically connected to the electrode 112 (the emitter) of the first switching element 11C, the electrode 122 (the source) of the second switching element 12C, and the electrode 131 (the anode) of the first protective element 13C. The lead 3G includes a terminal part 32G and a pad part 33G, as shown in FIG. 3. The terminal part 32G and the pad part 33G are connected to each other.

The terminal part 32G is a part of the lead 3G protruding from the sealing member 7. In the y direction, the terminal part 32G protrudes in the opposite side to the leads 4A-4H, 4J-4N, 4P-4R with respect to the pad part 33G, as shown in FIG. 3. The terminal part 32G is provided to connect the semiconductor device A1 to an external circuit. In the illustrated example, the terminal part 32G has an L-shape with a bend in the z1 side of the z direction.

The pad part 33G is covered by the sealing member 7. The pad part 33G does not overlap with the support substrate 51 in plan view, as shown in FIG. 3. The pad part 33G is disposed in the same position (the same height) as each of the pad parts 33A-33F in the z direction. As shown in FIG. 3, the pad part 33G is bonded to a wire 6F and electrically connect to the electrode 112 (the emitter) of the first switching element 11C, the electrode 122 (the source) of the second switching element 12C, and the electrode 131 (the anode) of the first protective element 13C via the wire 6F.

The lead 3Z is disposed in the z1 side of the z direction with respect to the lead 3A. The lead 3Z is electrically connected to none of the first switching parts 1 and the second switching parts 2. The lead 3Z includes a terminal part 32Z and a pad part 33Z, as shown in FIG. 3. The terminal part 32Z and the pad part 33Z are connected to each other.

The terminal part 32Z is a part of the lead 3Z protruding from the sealing member 7. In the y direction, the terminal part 32Z protrudes in the opposite side to the leads 4A-4H, 4J-4N, 4P-4R with respect to the pad part 33Z, as shown in FIG. 3. In the illustrated example, the terminal part 32Z has an L-shape with a bend in the z1 side of the z direction.

The pad part 33Z is covered by the sealing member 7. The pad part 33Z does not overlap with the support substrate 51 in plan view, as shown in FIG. 3. The pad part 33Z is disposed in the same position (the same height) as each of the pad parts 33A-33G in the z direction.

The lead 4A, the lead 4B, and the lead 4C are disposed in the x1 side of the x direction with respect to the lead 4D, as shown in FIG. 3. In the following, the lead 4A will be explained in detail, but the lead 4B and the lead 4C also include similar components. In this case, each component of the lead 4B and the lead 4C corresponds to each component in the lead 4A whose letter “A” is replaced by “B” and “C”, respectively.

The lead 4A includes a terminal part 42A and a pad part 43A, as shown in FIG. 3. Thus, as noted above, the lead 4B includes a terminal part 42B and a pad part 43B, and the lead 4C includes a terminal part 42C and a pad part 43C, as shown in FIG. 3.

The terminal part 42A is a part of the lead 4A protruding from the sealing member 7. In the y direction, the terminal part 42A protrudes in the opposite side to the leads 3A-3G, 3Z with respect to the pad part 43A, as shown in FIG. 3. The terminal part 42A is provided to connect the semiconductor device A1 to an external circuit. In the illustrated example, the terminal part 42A has an L-shape with a bend in the z1 side of the z direction.

The pad part 43A is covered by the sealing member 7. The electronic component 89U and any of the wires 6L are bonded to the pad part 43A, as shown in FIG. 3. Note that the electronic component 89V is bonded to the pad part 43B instead of the electronic component 89U and the electronic component 89W is bonded to the pad part 43C instead of the electronic component 89U. The shape of the pad part 43A is not limited to the illustrated example.

The leads 4D-4G are disposed in the x2 side of the x direction with respect to the lead 4C, as shown in FIG. 3.

In the following, the lead 4D will be explained in detail, but the leads 4E, 4F, 4G also include similar components. In this case, each component of the leads 4E, 4F and 4G corresponds to each component in the lead 4D whose letter “D” is replaced by “E”, “F” and “G”, respectively.

The lead 4D includes a terminal part 42D, a pad part 43D and a connection part 44D, as shown in FIG. 3. Thus, as described above, the lead 4E includes a terminal part 42E, a pad part 43E and a connection part 44E, the lead 4F includes a terminal part 42F, a pad part 43F and a connection part 44F, and the lead 4G includes a terminal part 42G, a pad part 43G and a connection part 44G, as shown in FIG. 3.

The terminal part 42D is a part of the lead 4D protruding from the sealing member 7. In the y direction, the terminal part 42D protrudes in the opposite side to the leads 3A-3G, 3Z with respect to the pad part 43D, as shown in FIG. 3. The terminal part 42D is provided to connect the semiconductor device A1 to an external circuit. In the illustrated example, the terminal part 42D has an L-shape with a bend in the z1 side of the z direction.

The pad part 43D is covered by the sealing member 7. As shown in FIG. 3, the pad part 43D is bonded to any of the wires 6L and electrically connected to the electrode 82 of the second control element 8B via the relevant wires 6L.

The connection part 44D is covered by the sealing member 7. The connection part 44D is connected to and interposed between the terminal part 42D and the pad part 43D, as shown in FIG. 3.

On the lead 4H, the second control element 8B is mounted. As shown in FIG. 3, the lead 4H includes a mounting part 41H, a terminal part 42H, a pad part 43H, a plurality of connection parts 44H and a projecting part 45H.

The mounting part 41H is covered by the sealing member 7. The second control element 8B is mounted on the mounting part 41H, as shown in FIG. 3. As explained above, the second control element 8B is fixed to the mounting part 41H by the bonding material 85. The mounting part 41H is spaced apart from the support substrate 51 in the z direction, as shown in FIG. 10.

The terminal part 42H is a part of the lead 4H protruding from the sealing member 7. In the y direction, the terminal part 42H protrudes in the opposite side to the leads 3A-3G, 3Z with respect to the mounting part 41H, as shown in FIG. 3. The terminal part 42H is provided to connect the semiconductor device A1 to an external circuit. In the illustrated example, the terminal part 42H has an L-shape with a bend in the z direction.

The pad part 43H is covered by the sealing member 7. The pad part 43H is adjacent to the mounting part 41H. The pad part 43H is bonded to any of the wires 6L, as shown in FIG. 3.

Each of the connection parts 44H is covered by the sealing member 7. The connection parts 44H include one interposed between and connected to the terminal part 42H and the pad part 43H and one interposed between and connected to the mounting part 41H and the projecting part 45H.

As shown in FIG. 3, the projecting part 45H extends in the y1 side of the y direction from the connection part 44H connected to the mounting part 41H, and protrudes from the sealing member 7.

On the lead 4R, the first control element 8A is mounted. The lead 4R includes a mounting part 41R, a terminal part 42R, a pad part 43R, and a connection part 44R, as shown in FIG. 3.

The mounting part 41R is covered by the sealing member 7. The first control element 8A is mounted on the mounting part 41R, as shown in FIG. 3. As explained above, the first control element 8A is fixed to the mounting part 41R by the bonding material 85. The mounting part 41R is spaced apart from the support substrate 51 in the z direction, as with the mounting part 41H.

The terminal part 42R is a part of the lead 4R protruding from the sealing member 7. In the y direction, the terminal part 42R protrudes in the opposite side to the leads 3A-3G, 3Z with respect to the mounting part 41R, as shown in FIG. 3. The terminal part 42R is provided to connect the semiconductor device A1 to an external circuit. In the illustrated example, the terminal part 42R has an L-shape with a bend in the z direction.

The pad part 43R is covered by the sealing member 7. The pad part 43R is adjacent to the mounting part 41R. The pad part 43R is bonded to any of the wires 6L, as shown in FIG. 3.

The connection part 44R is covered by the sealing member 7. The connection part 44R is interposed between and connected to the terminal part 42R and the pad part 43R.

The leads 4J-4N, 4P, 4Q are disposed in the x2 side of the x direction with respect to the lead 4H, as shown in FIG. 3. In the following, the lead 4Q will be explained in detail, but the leads 4J, 4K, 4L, 4M, 4N, 4P also include similar components. In this case, each component of the leads 4J, 4K, 4L, 4M, 4N, and 4P corresponds to each component in the lead 4Q whose letter “Q” is replaced by “J”, “K”, “L”, “M”, “N” and “P”, respectively.

The lead 4Q includes a terminal part 42Q, a pad part 43Q and a connection part 44Q, as shown in FIG. 3. Thus, as described above, the lead 4J includes a terminal part 42J, a pad part 43J and a connection part 44J, the lead 4K includes a terminal part 42K, a pad part 43K and a connection part 44K, the lead 4L includes a terminal part 42L, a pad part 43L and a connection part 44L, the lead 4M includes a terminal part 42M, a pad part 43M and a connection part 44M, the lead 4N includes a terminal part 42N, a pad part 43N and a connection part 44N, and the lead 4P includes a terminal part 42P, a pad part 43P and a connection part 44P, as shown in FIG. 3.

The terminal part 42Q is a part of the lead 4Q protruding from the sealing member 7. In the y direction, the terminal part 42Q protrudes in the opposite side to the leads 3A-3G, 3Z with respect to the pad part 43Q, as shown in FIG. 3. The terminal part 42Q is provided to connect the semiconductor device A1 to an external circuit. In the illustrated example, the terminal part 42Q has an L-shape with a bend in the z direction. In the x direction, each of the terminal parts 42Q, 42J-42N of the leads 4Q, 4J-4N is disposed between the terminal part 42H of the lead 4H and the terminal part 42R of the lead 4R, and the terminal part 42P of the lead 4P is offset in the x2 side of the x direction with respect to the terminal part 42R.

The pad part 43Q is covered by the sealing member 7. As shown in FIG. 3, the pad part 43Q is bonded to any of the wires 6L and electrically connected to the electrode 82 of the first control element 8A via the relevant wires 6L. In an example illustrated in FIG. 3, none of the wires 6L is bonded to the pad part 43P.

The connection part 44Q is covered by the sealing member 7. The connection part 44Q is connected to and interposed between the terminal part 42Q and the pad part 43Q, as shown in FIG. 3.

In the illustrated example, the terminal parts 42A-42C are arranged side by side in the x direction with a first pitch width d1 (see FIG. 3). Further, the terminal parts 42D-42H, 42J-42N, 42P-42R are arranged side by side in the x direction with a second pitch width d2 (see FIG. 3). The first pitch width d1 is larger than the second pitch width d2. A distance along the x direction between the terminal part 42C and the terminal part 42D corresponds to the first pitch width d1.

As shown in FIG. 8, the support substrate 51 supports the leads 3A-3D and is provided e.g. to transfer heat via these leads from each of the first switching parts 1 and the second switching parts 2 to the outside of the semiconductor device A1. The support substrate 51 is plate-like and rectangular in plan view. The support substrate 51 is made of an insulative material including ceramics such as alumina (Al₂O₃), silicon nitride (SiN), aluminum nitride (AlN), and zirconia-containing alumina. It is preferable that the support substrate 51 be made of ceramics in terms of strength, heat transfer coefficient, and insulation. However, the material of the support substrate 51 is not limited to this, and various other materials (e.g. an epoxy resin, silicon and the like) may be employed. It is preferable that the support substrate 51 be made of a material with higher heat transfer coefficient than the sealing member 7.

The support substrate 51 has a first surface 511, a second surface 512, a third surface 513, a fourth surface 514, a fifth surface 515, and a sixth surface 516, as shown in FIGS. 3 and 8-11. The first surface 511 and the second surface 512 are separated in the z direction, as shown in FIGS. 8-11. The first surface 511 faces upward in the z direction (the z1 side of the z direction), and the second surface 512 faces downward in the z direction (the z2 side of the z direction). As shown in FIG. 8, the mounting parts 311A, 312A, 313A, 31B, 31C, 31D are bonded to the first surface 511 via the bonding materials 39, respectively. The second surface 512 is exposed from the sealing member 7, as shown in FIGS. 8-11. The third surface 513, the fourth surface 514, the fifth surface 515, and the sixth surface 516 are located between the first surface 511 and the second surface 512 in the z direction, and are connected to them. The third surface 513 and the fourth surface 514 are separated in the x direction, as shown in FIGS. 3 and 8. The third surface 513 faces the x2 side in the x direction, and the fourth surface 514 faces the x1 side in the x direction. The fifth surface 515 and the sixth surface 516 are separated in the y direction, as shown in FIGS. 3 and 9-11. The fifth surface 515 faces the y2 side in the y direction, and the sixth surface 516 faces the y1 side in the y direction. In the illustrated example, each of the first surface 511, the second surface 512, the third surface 513, the fourth surface 514, the fifth surface 515 and the sixth surface 516 is flat.

The connection members 6 each electrically connect the two parts that are separated from each other. As understood from FIGS. 3-5, the connection members 6 include a plurality of wires 6A-6H, 6J-6L, 6Q. Each of the wires 6A-6H, 6J-6L, 6Q (each connection member 6) is a bonding wire. Each connection member 6 may be a conductive plate member, a bonding ribbon, or a plated wire instead of the wires 6A-6H, 6J-6L, 6Q.

As shown in FIG. 5, the wire 6A is bonded to the electrode 212 (the emitter) of the third switching element 21A, the electrode 222 (the source) of the fourth switching element 22A, and the electrode 231 (the anode) of the second protective element 23A. Hence, the electrode 212 of the third switching element 21A, the electrode 222 of the fourth switching element 22A, and the electrode 231 of the second protective element 23A are electrically connected to each other. Further, the wire 6A is bonded to the pad part 33B of the lead 3B, as shown in FIG. 3. Since the lead 3B is electrically connected to the first arm 1A (the electrode 111 of the first switching element 11A, the electrode 121 of the second switching element 12A, and the electrode 132 of the first protective element 13A), the electrode 212 of the third switching element 21A, the electrode 222 of the fourth switching element 22A, and the electrode 231 of the second protective element 23A are electrically connected to the electrode 111 of the first switching element 11A, the electrode 121 of the second switching element 12A, and the electrode 132 of the first protective element 13A via the lead 3B and the wire 6A.

As shown in FIG. 5, the wire 6B is bonded to the electrode 212 (the emitter) of the third switching element 21B, the electrode 222 (the source) of the fourth switching element 22B, and the electrode 231 (the anode) of the second protective element 23B. Hence, the electrode 212 of the third switching element 21B, the electrode 222 of the fourth switching element 22B, and the electrode 231 of the second protective element 23B are electrically connected to each other. Further, the wire 6B is bonded to the pad part 33C of the lead 3C, as shown in FIG. 3. Since the lead 3C is electrically connected to the second arm 1B (the electrode 111 of the first switching element 11B, the electrode 121 of the second switching element 12B, and the electrode 132 of the first protective element 13B), the electrode 212 of the third switching element 21B, the electrode 222 of the fourth switching element 22B, and the electrode 231 of the second protective element 23B are electrically connected to the electrode 111 of the first switching element 11B, the electrode 121 of the second switching element 12B, and the electrode 132 of the first protective element 13B via the lead 3C and the wire 6B.

As shown in FIG. 5, the wire 6C is bonded to the electrode 212 (the emitter) of the third switching element 21C, the electrode 222 (the source) of the fourth switching element 22C, and the electrode 231 (the anode) of the second protective element 23C. Hence, the electrode 212 of the third switching element 21C, the electrode 222 of the fourth switching element 22C, and the electrode 231 of the second protective element 23C are electrically connected to each other. Further, the wire 6C is bonded to the pad part 33D of the lead 3D, as shown in FIG. 3. Since the lead 3D is electrically connected to the third arm 1C (the electrode 111 of the first switching element 11C, the electrode 121 of the second switching element 12C, and the electrode 132 of the first protective element 13C), the electrode 212 of the third switching element 21C, the electrode 222 of the fourth switching element 22C, and the electrode 231 of the second protective element 23C are electrically connected to the electrode 111 of the first switching element 11C, the electrode 121 of the second switching element 12C, and the electrode 132 of the first protective element 13C via the lead 3D and the wire 6C.

As shown in FIG. 4, the wire 6D is bonded to the electrode 112 (the emitter) of the first switching element 11A, the electrode 122 (the source) of the second switching element 12A, and the electrode 131 (the anode) of the first protective element 13A. Hence, electrode 112 of the first switching element 11A, the electrode 122 of the second switching element 12A, and the electrode 131 of the first protective element 13A are electrically connected to each other. Further, the wire 6D is bonded to the pad part 33E of the lead 3E, as shown in FIG. 3. Thus, the lead 3E is electrically connected to the electrode 112 of the first switching element 11A, the electrode 122 of the second switching element 12A, and the electrode 131 of the first protective element 13A via the wire 6D.

As shown in FIG. 4, the wire 6E is bonded to the electrode 112 (the emitter) of the first switching element 11B, the electrode 122 (the source) of the second switching element 12B, and the electrode 131 (the anode) of the first protective element 13B. Hence, electrode 112 of the first switching element 11B, the electrode 122 of the second switching element 12B, and the electrode 131 of the first protective element 13B are electrically connected to each other. Further, the wire 6E is bonded to the pad part 33F of the lead 3F, as shown in FIG. 3. Thus, the lead 3F is electrically connected to the electrode 112 of the first switching element 11B, the electrode 122 of the second switching element 12B, and the electrode 131 of the first protective element 13B via the wire 6E.

As shown in FIG. 4, the wire 6F is bonded to the electrode 112 (the emitter) of the first switching element 11C, the electrode 122 (the source) of the second switching element 12C, and the electrode 131 (the anode) of the first protective element 13C. Hence, electrode 112 of the first switching element 11C, the electrode 122 of the second switching element 12C, and the electrode 131 of the first protective element 13C are electrically connected to each other. Further, the wire 6F is bonded to the pad part 33G of the lead 3G, as shown in FIG. 3. Thus, the lead 3G is electrically connected to the electrode 112 of the first switching element 11C, the electrode 122 of the second switching element 12C, and the electrode 131 of the first protective element 13C via the wire 6F.

The wires 6G are connected to the electrode 113 of each first switching element 11 and the electrode 81 of the first control element 8A, as shown in FIG. 4. The wires 6G transmit the above-described first drive signal corresponding to each of the first switching elements 11.

The wires 6H are connected to the electrode 123 of each first switching element 11 and the electrode 81 of the first control element 8A, as shown in FIG. 4. The wires 6H transmit the above-described first drive signal corresponding to each of the second switching elements 12.

The wires 6Q are connected to the electrode 213 of each third switching element 21 and the electrode 81 of the second control element 8B, as shown in FIG. 5. The wires 6Q transmit the above-described second drive signal corresponding to each of the third switching elements 21.

The wires 6J are connected to the electrode 223 of each fourth switching element 22 and the electrode 81 of the second control element 8B, as shown in FIG. 5. The wires 6J transmit the above-described second drive signal corresponding to each of the fourth switching elements 22.

Each wire 6K is connected to the electrode 222 of each fourth switching element 22 and the electrode 83 of the second control element 8B. Each of the wires 6K transmits the detection signal for detecting the conduction state of either the fourth arm 2A, the fifth arm 2B, or the sixth arm 2C. In the illustrated example, the detection signal is the source current (or the source voltage) of each fourth switching element 22.

Each wire 6L is connected to the electrode 82 of the first control element 8A or the electrode 82 of the second control element 8B and one of the electronic components 89U, 89V, 89W or one of the pad parts 43A-43H, 43J-43N, 43Q, 43R of the leads 4A-4H, 4J-4N, 4Q, 4R. Hence, each wire 6L electrically connects the first control element 8A or the second control element 8B to the respective leads 4A-4H, 4J-4N, 4Q, 4R.

In the connection members 6, each wire 6A-6F has a larger wire diameter than each wire 6G, 6H, 6J-6L, 6Q. This is because, when the semiconductor device A1 is configured as an IPM, a higher voltage is applied to, and a larger current flows through, the leads 3A-3G compared to the leads 4A-4F. Each wire 6A-6F is, for example, made of A1 or an A1 alloy. The constituent material of each wire 6A-6F may be Au, an Au alloy, Cu or a Cu alloy instead of A1 or an A1 alloy. Each wire 6G, 6H, 6J-6L, 6Q is, for example, made of Au or an Au alloy. The constituent material of each wire 6G, 6H, 6J-6L, 6Q may be A1 an A1 alloy, Cu or a Cu alloy instead of Au or an Au alloy.

As shown in FIGS. 1-3 and 6-11, the sealing member 7 covers the first switching parts 1, the second switching parts 2, the first control element 8A, the second control element 8B, the electronic components 89U, 89V, 89W, a part of the respective leads 3A-3G, 3Z, a part of the respective leads 4A-4H, 4J-4N, 4P-4R, a part of the support substrate 51, and the connection members 6. The sealing member 7 is a black epoxy resin. The sealing member 7 has a resin obverse surface 71, a resin reverse surface 72, and a plurality of resin side surfaces 73-76.

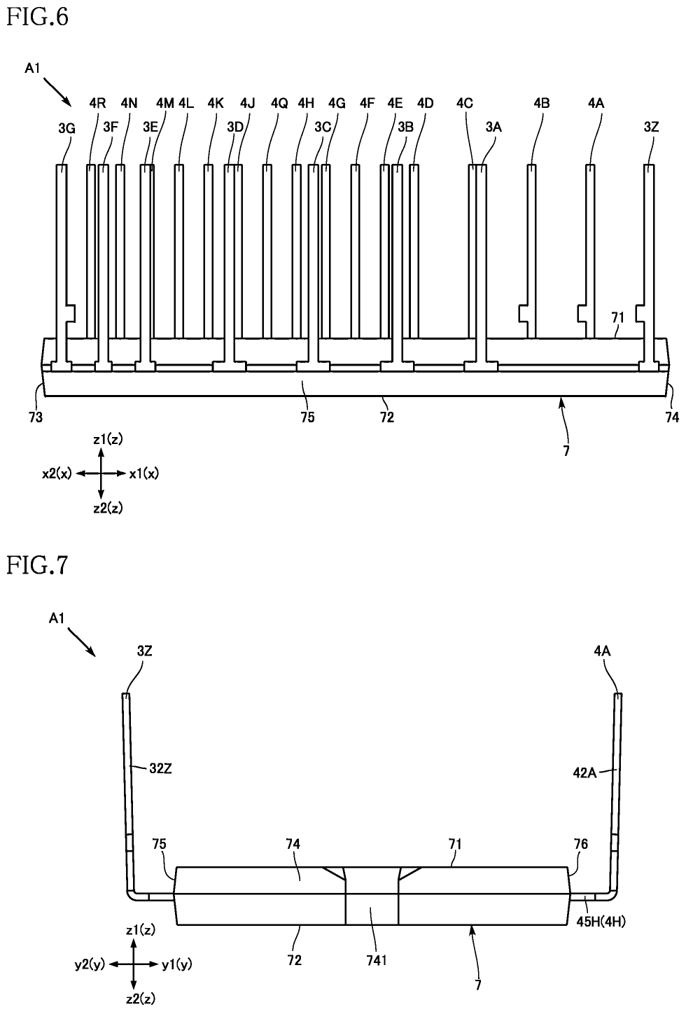

The resin obverse surface 71 and the resin reverse surface 72 are separated in the z direction, as shown in FIGS. 6-11. The resin obverse surface 71 faces upward in the z direction (the z1 side of the z direction), and resin reverse surface 72 faces downward in the z direction (the z2 side of the z direction). Each of the resin obverse surface 71 and the resin reverse surface 72 is flat (or generally flat). Each of the resin side surfaces 73-76 is located between the resin obverse surface 71 and the resin reverse surface 72 in the z direction, and are connected to them. The paired resin side surfaces 73, 74 are separated in the x direction, as shown in FIGS. 2, 3, 8. The paired resin side surfaces 73, 74 mutually face opposite in the x direction. The paired resin side surfaces 75, 76 are separated in the y direction, as shown in FIGS. 2, 3 and 9-11. The paired resin side surfaces 75, 76 mutually face opposite in the y direction. The resin side surface 73 is provided with a recess 731 that is recessed in the x direction, as shown in FIGS. 2 and 3. The resin side surface 74 is provided with a recess 741 that is recessed in the x direction. The recess 731 and the recess 741 are provided, e.g. to fix when mounting the semiconductor device A1. The resin side surface 76 is provided with recesses 761 that are each recessed in the y direction, as shown in FIGS. 2 and 3.

In the semiconductor device A1, a first DC voltage applied to the terminal part 32A (the lead 3A) and the terminal part 32E (the lead 3E) is converted into a first AC voltage by each switching operation of the first arm 1A and the fourth arm 2A. Then, the first AC voltage is output from the terminal part 32B (the lead 3B). Further, a second DC voltage applied to the terminal part 32A (the lead 3A) and the terminal part 32F (the lead 3F) is converted into a second AC voltage by each switching operation of the second arm 1B and the fifth arm 2B. Then, the second AC voltage is output from the terminal part 32C (the lead 3C). Further, a third DC voltage applied to the terminal part 32A (the lead 3A) and the terminal part 32G (the lead 3G) is converted into a third AC voltage by each switching operation of the third arm 1C and the sixth arm 2C. Then, the third AC voltage is output from the terminal part 32D (the lead 3D).

As shown in FIG. 12, the circuit configuration of the semiconductor device A1 configured as explained above is as follows. In the example shown in FIG. 12, each first switching element 11A, 11B, 11C and each third switching element 21A, 21B, 21C are IGBTs, and each second switching element 12A, 12B, 12C and each fourth switching element 22A, 22B, 22C are MOSFETs. Further, each first protective element 13A, 13B, 13C and each second protective element 23A, 23B, 23C are Schottky barrier diodes. Note that FIG. 12 illustrates parasitic diodes in each second switching element 12A, 12B, 12C and each fourth switching element 22A, 22B, 22C.

The collector (the electrode 211) of each third switching element 21A, 21B, 21C, the drain (the electrode 221) of each fourth switching element 22A, 22B, 22C, and the cathode (the electrode 131) of each second protective element 23A, 23B, 23C are connected to each other and to the P terminal (the lead 3A).

The emitter (the electrode 212) of the third switching element 21A, the source (the electrode 222) of the fourth switching element 22A, and the anode (the electrode 231) of the second protective element 23A are connected to the collector (the electrode 111) of the first switching element 11A, the drain (the electrode 121) of the second switching element 12A, and the cathode (the electrode 132) of the first protective element 13A via a connection point N1. The connection point N1 is connected to the U terminal (the lead 3B).

The emitter (the electrode 212) of the third switching element 21B, the source (the electrode 222) of the fourth switching element 22B, and the anode (the electrode 231) of the second protective element 23B are connected to the collector (the electrode 111) of the first switching element 11B, the drain (the electrode 121) of the second switching element 12B, and the cathode (the electrode 132) of the first protective element 13B via a connection point N2. The connection point N2 is connected to the V terminal (the lead 3C).

The emitter (the electrode 212) of the third switching element 21C, the source (the electrode 222) of the fourth switching element 22C, and the anode (the electrode 231) of the second protective element 23C are connected to the collector (the electrode 111) of the first switching element 11C, the drain (the electrode 121) of the second switching element 12C, and the cathode (the electrode 132) of the first protective element 13C via a connection point N3. The connection point N3 is connected to the W terminal (the lead 3D).

The emitter (the electrode 112) of the first switching element 11A, the source (the electrode 122) of the second switching element 12A, and the anode (the electrode 131) of the first protective element 13A are connected to the NU terminal (the lead 3E). The emitter (the electrode 112) of the first switching element 11B, the source (the electrode 122) of the second switching element 12B, and the anode (the electrode 131) of the first protective element 13B are connected to the NV terminal (the lead 3F). The emitter (the electrode 112) of the first switching element 11C, the source (the electrode 122) of the second switching element 12C, and the anode (the electrode 131) of the first protective element 13C are connected to the NW terminal (the lead 3G).

The voltage level applied to the U terminal (the lead 3B), the V terminal (the lead 3C), and the W terminal (the lead 3D) is, for example, approximately 0V to 650V. On the other hand, the voltage level applied to the NU terminal (the lead 3E), the NV terminal (the lead 3F), and the NW terminal (the lead 3G) is, for example, approximately 0V, which is less than the voltage level applied to the U terminal (the lead 3B), the V terminal (the lead 3C), and the W terminal (the lead 3D)

The gate (the electrode 213) of each third switching element 21A, 21B, 21C, and the gate (the electrode 223) of each fourth switching element 22A, 22B, 22C are connected to the second control element 8B. The source (the electrode 222) of each fourth switching element 22A, 22B, 22C is connected to the second control element 8B. The gate (the electrode 113) of each first switching element 11A, 11B, 11C, and the gate (the electrode 123) of each second switching element 12A, 12B, 12C are connected to the first control element 8A.

The LINU terminal (the lead 4Q), the LINV terminal (the lead 4J), and the LINW terminal (the lead 4K) are connected to an external gate control circuit and receives the first input signal from the external gate control circuit. The HINU terminal (the lead 4E), the HINV terminal (the lead 4F), and the HINW terminal (the lead 4G) are connected to the gate control circuit (not shown) and receives the second input signal from the gate control circuit.

The first control element 8A is electrically connected to the LINU terminal (the lead 4Q), the LINV terminal (the lead 4J), the LINW terminal (the lead 4K), the second VCC terminal (the lead 4L), the FO terminal (the lead 4M), the CIN terminal (the lead 4N), and the second GND terminal (the lead 4R). The first control element 8A is also electrically connected to the first GND terminal (the lead 4H). The second VCC terminal is a terminal to supply a source voltage VCC to the first control element 8A. The first control element 8A receives the first input signal from the LINU terminal, the LINV terminal, and the LINW terminal. The first control element 8A generates the above-described first drive signal (e.g. a gate voltage) depending on the first input signal. Then, the generated first drive signal is input to the gate (the electrode 113) of each first switching element 11A, 11B, 11C and the gate (the electrode 123) of each second switching element 12A, 12B, 12C.

The second control element 8B is electrically connected to the VBU terminal (the lead 4A), the VBV terminal (the lead 4B), the VBW terminal (the lead 4C), the HINU terminal (the lead 4D), the HINV terminal (the lead 4E), the HINW terminal (the lead 4F), the first VCC terminal (the lead 4G) and the first GND terminal (the lead 4H). The second control element 8B is also electrically connected to the second GND terminal (the lead 4R). The first VCC terminal is a terminal to supply a source voltage VCC to the second control element 8B. The second control element 8B receives the second input signal from the HINU terminal, the HINV terminal, and the HINW terminal. The second control element 8B generates the above-described second drive signal (e.g. a gate voltage) depending on the second input signal. Then, the generated second drive signal is input to the gate (the electrode 213) of each third switching element 21A, 21B, 21C and the gate (the electrode 223) of each fourth switching element 22A, 22B, 22C.

In the example shown in FIG. 12, the first GND terminal (the lead 4H) and the second GND terminal (the lead 4R) are connected to each other within the semiconductor device A1 and have the same potential. Unlike this configuration, the first GND terminal (the lead 4H) and the second GND terminal (the lead 4R) may be separated to each other within the semiconductor device A1 and have different potentials.

Advantages of the semiconductor device A1 may be as follows.

The semiconductor device A1 includes the first switching parts 1 and the first control element 8A. Each of the first switching parts 1 includes the first switching element 11 and the second switching element 12. The first switching element 11 of each first switching part 1 is connected to the first control element 8A via the wire 6G. The wire 6G is an example of a “first connection member”. The second switching element 12 of each first switching part 1 is connected to the first control element 8A via the wire 6H. The wire 6H is an example of a “second connection member”. Further, the first switching element 11 and the second switching element 12 of each first switching part 1 are disposed around the first control element 8A in plan view. Such a configuration allows reducing the distance from the first control element 8A to each first switching element 11 and each second switching element 12 in plan view. This facilitates wiring from the first control element 8A to each first switching element 11 and each second switching element 12. In addition, the reduction in the distance from the first control element 8A to each first switching element 11 and each second switching element 12 in plan view results in shortening of the wire length of each of the wire 6G and the wire 6H. This reduces the cost of the wires 6G, 6H while reducing the resistive and inductive components of these wires. Further, shortening of the wire length of each of the wire 6G and the wire 6H is advantageous for preventing the wire sweep of these wires 6G, 6H. In light of the foregoing, the semiconductor device A1 has a preferable structure for operating the switching elements (the first switching element 11 and the second switching element 12) as one first switching part 1. The same is applied to the relationship between the second switching parts 2 (the third switching elements 21 and the fourth switching elements 22) and the second control element 8B. That is, the third switching element 21 and the fourth switching element 22 of each second switching part 2 are disposed around the second control element 8B in plan view, so that the semiconductor device A1 has a preferable structure for operating the switching elements (the third switching element 21 and the fourth switching element 22) as one second switching part 2.

The semiconductor device A1 includes each first switching part 1 in which the first switching element 11 is an IGBT and the second switching element 12 is a MOSFET. Generally, IGBTs and MOSFETs exhibit the following electrical properties due to their differences in physical properties and structures. For example, MOSFETs have a higher switching speed and a lower switching loss than IGBTs. On the other hand, IGBTs have lower on-resistance and lower steady-state loss than MOSFETs when large current flows. Thus, when each first switching part 1 switches (turns on and off), switching loss are reduced by controlling the current flowing through the second switching element 12 (MOSFET) to increase. Further, when each first switching part 1 is in the steady state, steady-state loss is reduced by controlling the current flowing through the first switching element 11 (IGBT) to increase. Therefore, the semiconductor device A1 has an advantage to reduce both switching loss and steady-state loss, thereby reducing power loss. In other words, the semiconductor device A1 improves conversion efficiency. The same is applied to the relationship between the third switching elements 21 and the fourth switching elements 22 in each second switching part 2. That is, since the third switching element 21 is an IGBT and the fourth switching element 22 is a MOSFET, both switching loss and steady-state loss as well as power loss can be reduced.

The semiconductor device A1, as shown in FIG. 4, includes the first control element 8A that is offset in the y1 side of the y direction with respect to the edge 302 of the mounting part 31C at the y1 side of the y direction. Further, the edge 302 of the mounting part 31C at the y1 side of the y direction is offset in the y2 side of the y direction with respect to the edge 301 of the mounting part 31B at the y1 side of the y direction and the edge 303 of the mounting part 31D at the y1 side of the y direction. Such a configuration results in the position of the mounting part 31C that is arranged to be depressed in the y direction with respect to the two mounting parts 31B, 31D. Thus, the first control element 8A is disposed in the depressed area, which allows the first switching element 11 and the second switching element 12 of each first switching part 1 to be disposed around the first control element 8A. Further, it is possible to reduce the y-direction size of the semiconductor device A1. Hence, it is possible to prevent the semiconductor device A1 from increasing the plan view size in the configuration to operate the switching elements (the first switching element 11 and the second switching element 12) as one first switching part 1.

The semiconductor device A1, as shown in FIG. 5, includes the second control element 8B that is offset in the y1 side of the y direction with respect to the edge 305 of the mounting part 312A at the y1 side of the y direction. Further, the edge 305 of the mounting part 312A at the y1 side of the y direction is offset in the y2 side of the y direction with respect to the edge 304 of the mounting part 311A at the y1 side of the y direction and the edge 306 of the mounting part 313A at the y1 side of the y direction. Such a configuration results in the position of the mounting part 312A that is arranged to be depressed in the y direction with respect to the two mounting parts 311A, 313A. Thus, the second control element 8B is disposed in the depressed area, which allows the third switching element 21 and the fourth switching element 22 of each second switching part 2 to be disposed around the second control element 8B. Further, it is possible to reduce the y-direction size of the semiconductor device A1. Hence, it is possible to prevent the semiconductor device A1 from increasing the plan view size in the configuration to operate the switching elements (the third switching element 21 and the fourth switching element 22) as one second switching part 2.

Other embodiments and variations of the semiconductor device according to the present disclosure are explained below. The configurations of various parts in these embodiments and variations can be combined in any way as long as the variation is technically compatible.

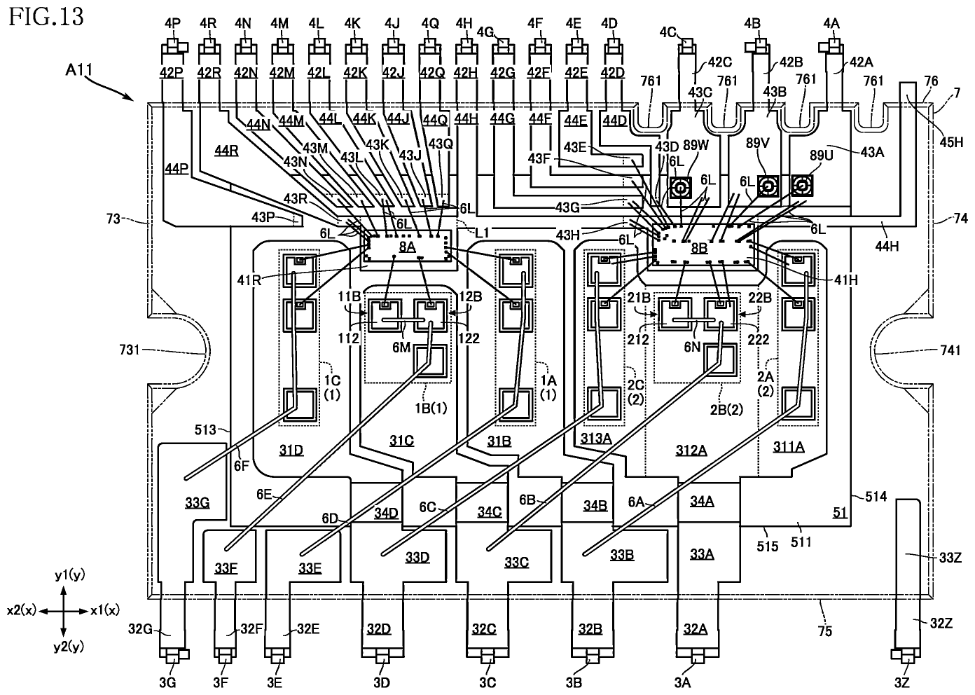

FIG. 13 illustrates a semiconductor device A11 according to a first variation of the first embodiment. The semiconductor device A11 differs from the semiconductor device A1 as follows. The electrode 112 of the first switching element 11B and the electrode 122 of the second switching element 12B are connected to each other by the wire 6M instead of the wire 6E, as shown in FIG. 13. Similarly, the electrode 212 of the third switching element 21B and the electrode 222 of the fourth switching element 22B are connected to each other by the wire 6N instead of the wire 6B, as shown in FIG. 13.

Each wire 6M, 6N is a bonding wire, as with the wires 6A-6F. The wire 6M is bonded to the electrode 112 of the first switching element 11B and the electrode 122 of the second switching element 12B. The wire 6N is bonded to the electrode 212 of the third switching element 21B and the electrode 222 of the fourth switching element 22B.

The semiconductor device A11 according to the present variation has the same advantages as the semiconductor device A1. Further, it is easy to form each wire 6B, 6E in the semiconductor device A11 for the following reasons. In the semiconductor device A1, the wire 6E includes a first part extending from a portion bonded to the electrode 112 of the first switching element 11B to another portion bonded to the electrode 122 of the second switching element 12B, and also includes a second part extending from the portion bonded to the electrode 122 of the second switching element 12B to a portion bonded to the electrode 131 of the first protective element 13B, where the first and second parts are at generally right angles in plan view. In order to bend wires at generally right angles, more advanced wire bonding technology is required. On the other hand, the semiconductor device A11 does not need to bend the wire 6E at generally right angles, because the electrode 112 of the first switching element 11B and the electrode 122 of the second switching element 12B are connected by an additional wire 6M. Therefore, it is easy to form the wire 6E in the semiconductor device A11. The same is applied to the wire 6B. In other words, the wire 6B is not needed to bend at right angles, because the electrode 212 of the third switching element 21B and the electrode 222 of the fourth switching element 22B are connected by an additional wire 6N. Therefore, it is easy to form the wire 6B in the semiconductor device A11.

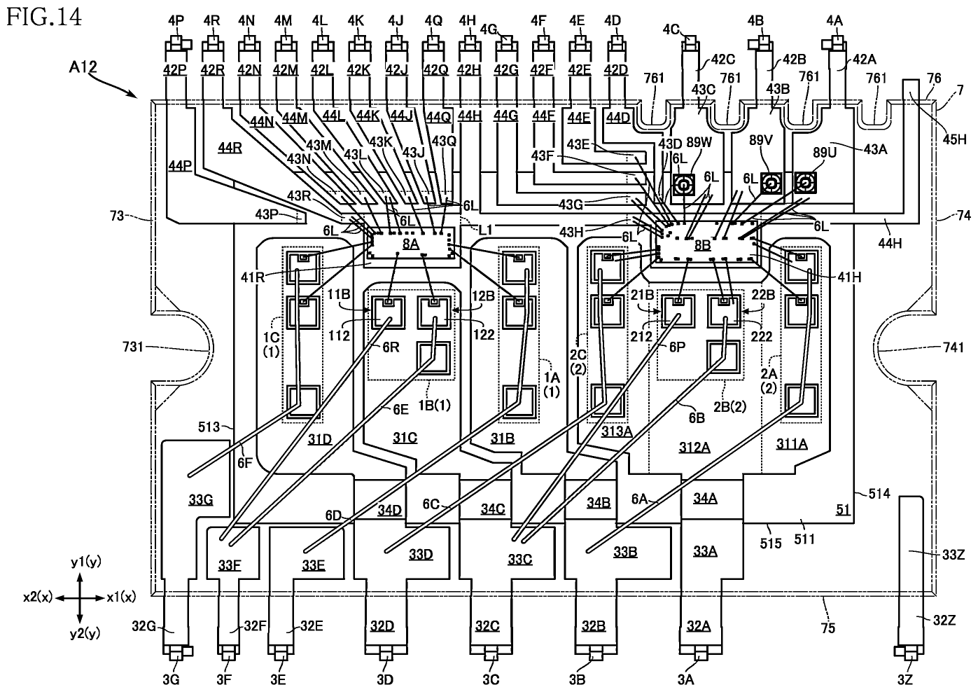

FIG. 14 illustrates a semiconductor device A12 according to a second variation of the first embodiment. The semiconductor device A12 differs from the semiconductor device A1 as follows. The electrode 112 of the first switching element 11B is electrically connected to the pad part 33F (the lead 3F) by the wire 6R instead of the wire 6E, as shown in FIG. 14. Similarly, the electrode 212 of the third switching element 21B is electrically connected to the pad part 33C (the lead 3C) by the wire 6P instead of the wire 6B, as shown in FIG. 14.

Each wire 6R, 6P is a bonding wire, as with the wires 6A-6F. The wire 6R is bonded to the electrode 112 of the first switching element 11B and the pad part 33F. The wire 6E is not bonded to the electrode 112 of the first switching element 11B but to the electrode 122 of the second switching element 12B, the electrode 131 of the first protective element 13B, and the pad part 33F. The wire 6P is bonded to the electrode 212 of the third switching element 21B and the pad part 33C. The wire 6B is not bonded to the electrode 212 of the third switching element 21B but to the electrode 222 of the fourth switching element 22B, the electrode 231 of the second protective element 23B, and the pad part 33C.

The semiconductor device A12 according to the present variation has the same advantages as the semiconductor device A1. Further, the semiconductor device A12 does not require each wire 6B, 6E to be bent at generally right angles, and thus it is easy to form each wire 6B, 6E, as with the semiconductor device A11.

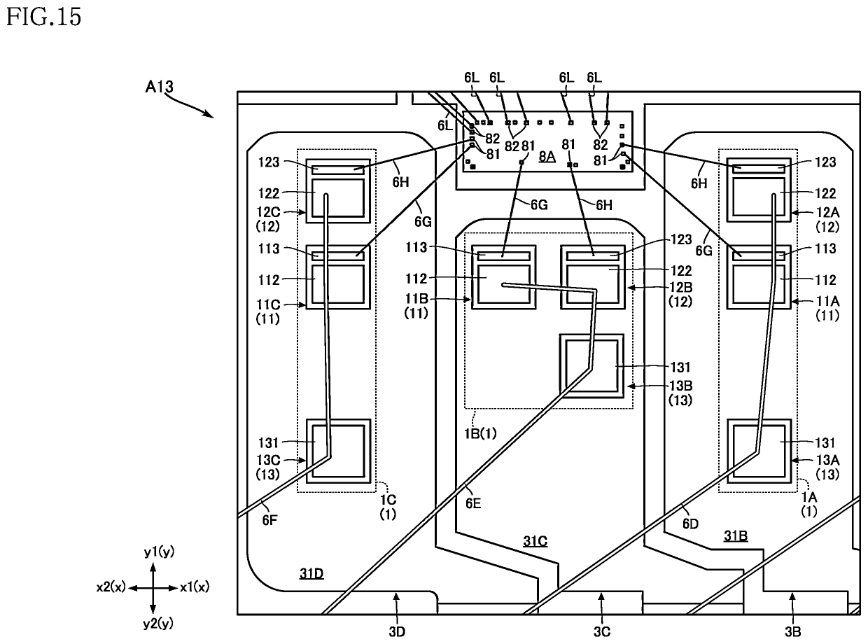

FIG. 15 illustrates a semiconductor device A13 according to a third variation of the first embodiment. The semiconductor device A13 differs from the semiconductor device A1 as follows. They differ in the shape and size of the electrode 113 on the element obverse surface 11a of each first switching element 11 in plan view, as shown in FIG. 15. They also differ in the shape and size of the electrode 123 on each second switching element 12 in plan view.

In the semiconductor device A13, the electrode 113 on each first switching element 11 has a band-like shape extending in the x direction in plan view, as shown in FIG. 15. Further, the electrode 123 on each second switching element 12 has a band-like shape extending in the x direction in plan view, as shown in FIG. 15.

Although not shown in figures, it can be varied in shape and size in plan view of the electrode 213 on each third switching element 21 and the electrode 223 on each fourth switching element 22, as with the electrode 113 on each first switching element 11 and the electrode 123 on each second switching element 12.

The semiconductor device A13 according to the present variation has the same advantages as the semiconductor device A1. Further, it is easy to form each wire 6G, 6H in the semiconductor device A13 for the following reasons. The electrode 113 on each first switching element 11 of the semiconductor device A13 is larger than the electrode 113 on each first switching element 11 of the semiconductor device A1, which enlarges an area where the wire 6G can be bonded. This allows the semiconductor device A13 to improve the degree of freedom for the position where each wire 6G is bonded in the electrode 113 on each first switching element 11, so that it is easy to form each wire 6G. Further, the electrode 113 on each first switching element 11 reaches near the periphery of each first switching element 11 in plan view, hence shortening the length of each wire 6G. Similarly, the electrode 123 on each second switching element 12 of the semiconductor device A13 is larger than the electrode 123 on each second switching element 12 of the semiconductor device A1, which enlarges an area where the wire 6H can be bonded. This allows the semiconductor device A13 to improve the degree of freedom for the position where each wire 6H is bonded in the electrode 123 on each second switching element 12, so that it is easy to form each wire 6H. Further, the electrode 123 on each second switching element 12 reaches near the periphery of each second switching element 12 in plan view, hence shortening the length of each wire 6H. The same is applied to the wire 6Q bonded to the electrode 213 of each third switching element 21, and to the wire 6J bonded to the electrode 223 of each fourth switching element 22.

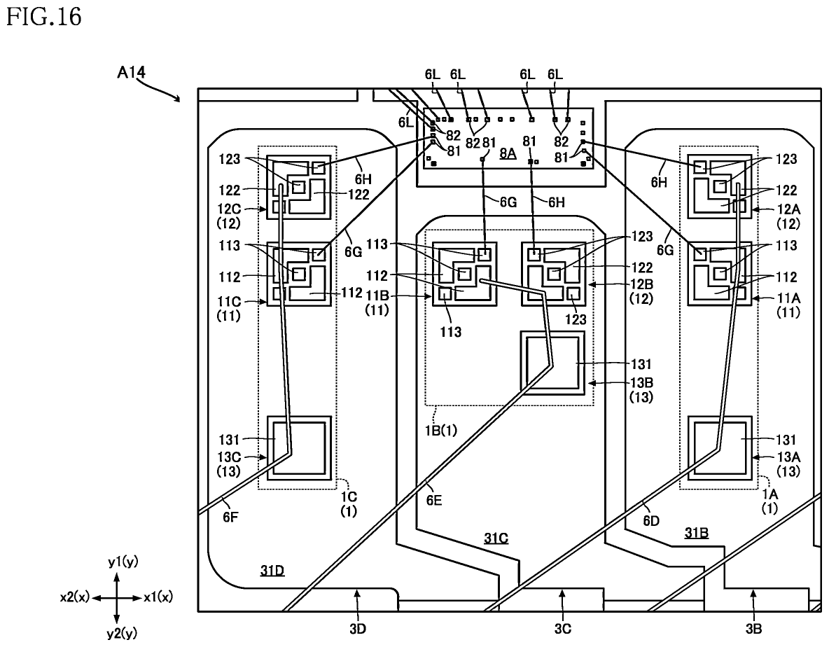

FIG. 16 illustrates a semiconductor device A14 according to a fourth variation of the first embodiment. The semiconductor device A14 differs from the semiconductor device A1 as follows. The semiconductor device A14 differs in that the electrodes 113 are provided on the element obverse surface 11a of each first switching element 11, as shown in FIG. 16. Further, the electrodes 123 are provided on the element obverse surface 12a of each second switching element 12. Although not shown in figures, the electrodes 213 may be provided on the element obverse surface 21a of each third switching element 21, and the electrodes 223 may be provided on the element obverse surface 22a of each fourth switching element 22.

The semiconductor device A14 according to the present variation has the same advantages as the semiconductor device A1. Further, it is easy to form each wire 6G, 6H in the semiconductor device A14 for the following reasons. The semiconductor device A14 includes each first switching element 11 with the electrodes 113 so as to improve the degree of freedom for the position where each wire 6G is bonded. Therefore, it is easy to form the wire 6G in the semiconductor device A14. Similarly, the semiconductor device A14 includes each second switching element 12 with the electrodes 123 so as to improve the degree of freedom for the position where each wire 6H is bonded. Therefore, it is easy to form the wire 6H in the semiconductor device A14. The same is applied to the wire 6Q bonded to the electrode 213 of each third switching element 21, and the wire 6J bonded to the electrode 223 of each fourth switching element 22.

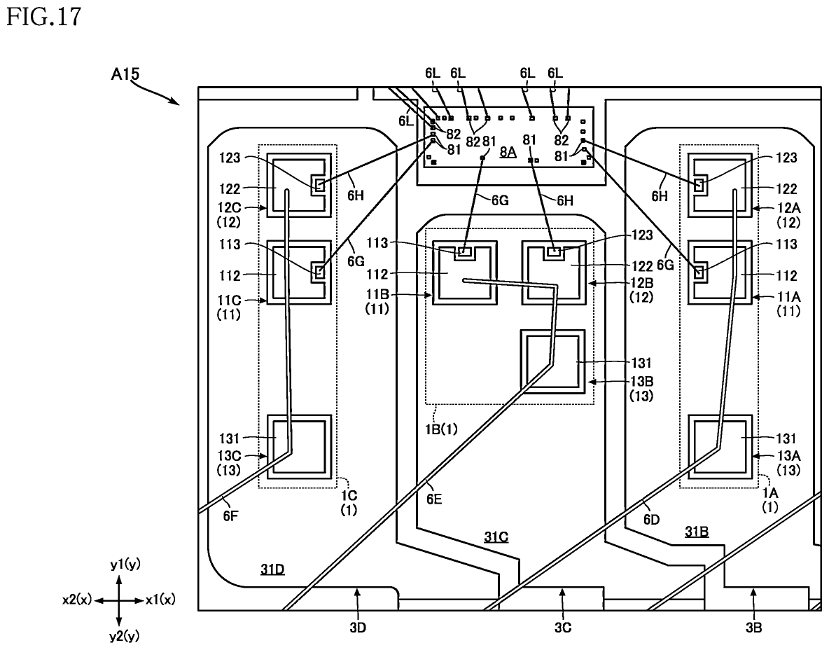

FIG. 17 illustrates a semiconductor device A15 according to a fifth variation of the first embodiment. The semiconductor device A15 differs from the semiconductor device A1 as follows. They differ in the arrangement of the electrodes 113 on the element obverse surface 11a of each first switching element 11, as shown in FIG. 17. Further, they differ in the arrangement of the electrodes 123 on the element obverse surface 12a of each second switching element 12.

In the semiconductor device A15, the electrode 113 on the first switching element 11A and the electrode 123 on the second switching element 12A are arranged based on the relative position of the mounting part 31B and the first control element 8A, as shown in FIG. 17. Specifically, the mounting part 31B is offset in the x1 side of the x direction with respect to the first control element 8A in the x direction, so that the electrode 113 on the first switching element 11A and the electrode 123 on the second switching element 12A are disposed in the x2 side of the x direction.

In the semiconductor device A15, the electrode 113 on the first switching element 11B and the electrode 123 on the second switching element 12B are arranged based on the relative position of the mounting part 31C and the first control element 8A, as shown in FIG. 17. Specifically, the mounting part 31C is offset in the y2 side of the y direction with respect to the first control element 8A in the y direction, so that the electrode 113 on the first switching element 11B and the electrode 123 on the second switching element 12B are disposed in the y1 side of the y direction.

In the semiconductor device A15, the electrode 113 on the first switching element 11C and the electrode 123 on the second switching element 12C are arranged based on the relative position of the mounting part 31D and the first control element 8A, as shown in FIG. 17. Specifically, the mounting part 31D is offset in the x2 side of the x direction with respect to the first control element 8A in the x direction, so that the electrode 113 on the first switching element 11C and the electrode 123 on the second switching element 12C are disposed in the x1 side of the x direction.

As explained above, in the semiconductor device A15, the electrode 113 on each first switching element 11 and the electrode 123 on each second switching element 12 are disposed near the first control element 8A, which is centered therebetween.

The semiconductor device A15 according to the present variation has the same advantages as the semiconductor device A1.

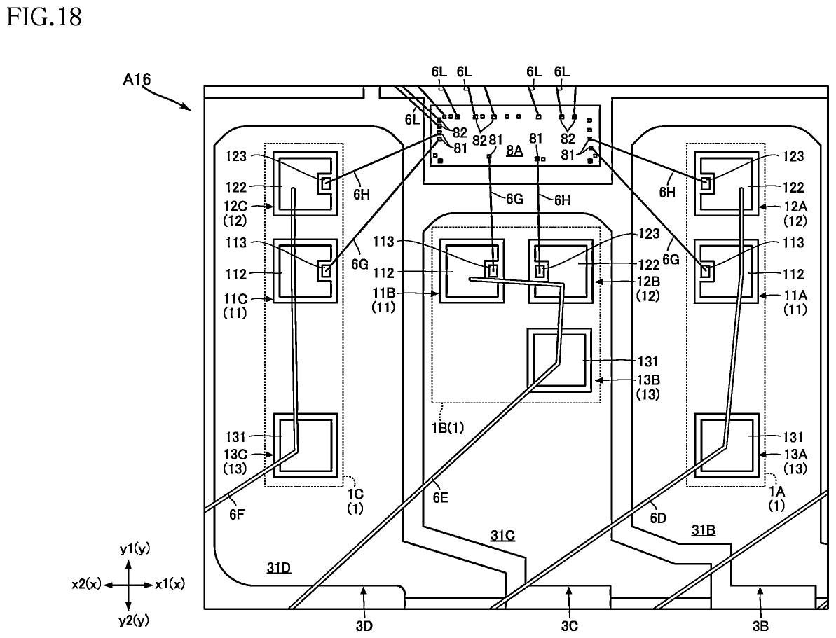

FIG. 18 illustrates a semiconductor device A16 according to a sixth variation of the first embodiment. The semiconductor device A16 differs from the semiconductor device A15 (the fifth variation of the first embodiment) as follows. They differ in the arrangement of the electrodes 113 on the first switching element 11B and the electrodes 123 on the second switching element 12B, as shown in FIG. 18.

In the semiconductor device A16, the electrode 113 on the first switching element 11B and the electrode 123 on the second switching element 12B are disposed to face each other in the x direction, as shown in FIG. 18. With such a configuration, the electrode 113 of each first switching element 11 and the electrode 123 of each second switching element 12 are symmetrically arranged with respect to the center of the first control element 8A in the x direction.

The semiconductor device A16 according to the present variation has the same advantages as the semiconductor device A1.

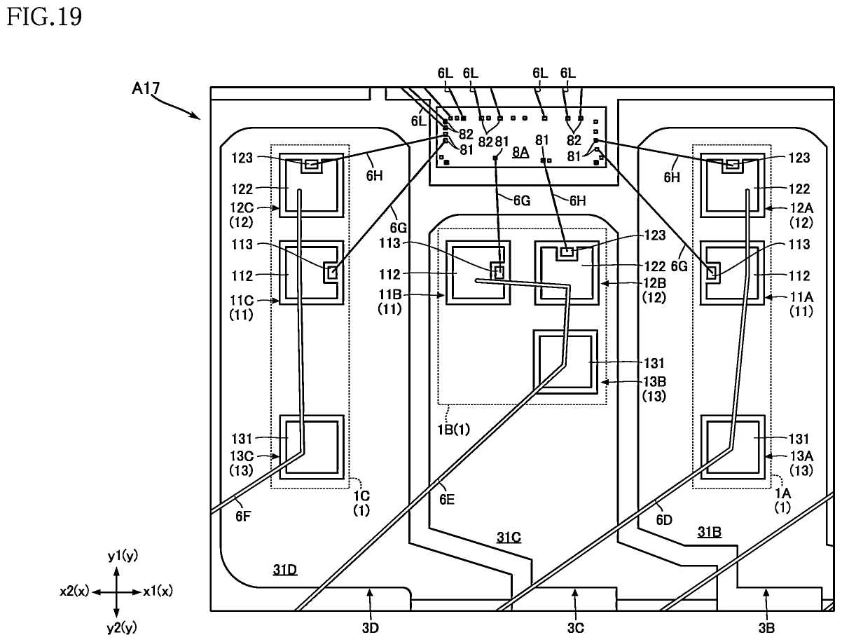

FIG. 19 illustrates a semiconductor device A17 according to a seventh variation of the first embodiment. The semiconductor device A17 differs from the semiconductor device A1 as follows. The semiconductor device A17 differs in that the electrode 113 on each first switching element 11 is disposed in either x1 side or x2 side of the x direction while the electrode 123 on each second switching element 12 is disposed in the y1 side of the y direction, as shown in FIG. 19. That is, the control electrodes (e.g. gates) are arranged differently for types of switching elements.

The semiconductor device A17 according to the present variation has the same advantages as the semiconductor device A1. In the semiconductor device A17, since the control electrodes (e.g. gates) are arranged differently for types of the switching elements, even if each first switching element 11 and each second switching element 12 have the same (or generally same) shape and size in plan view, it is possible to distinguish the first switching element 11 and the second switching element 12.

Although not shown in figures, in the fifth to seventh variations of the first embodiment, the electrode 213 on each third switching element 21 and the electrode 223 on each fourth switching element 22 may also be disposed like the electrode 113 on each first switching element 11 and the electrode 123 on each second switching element 12.

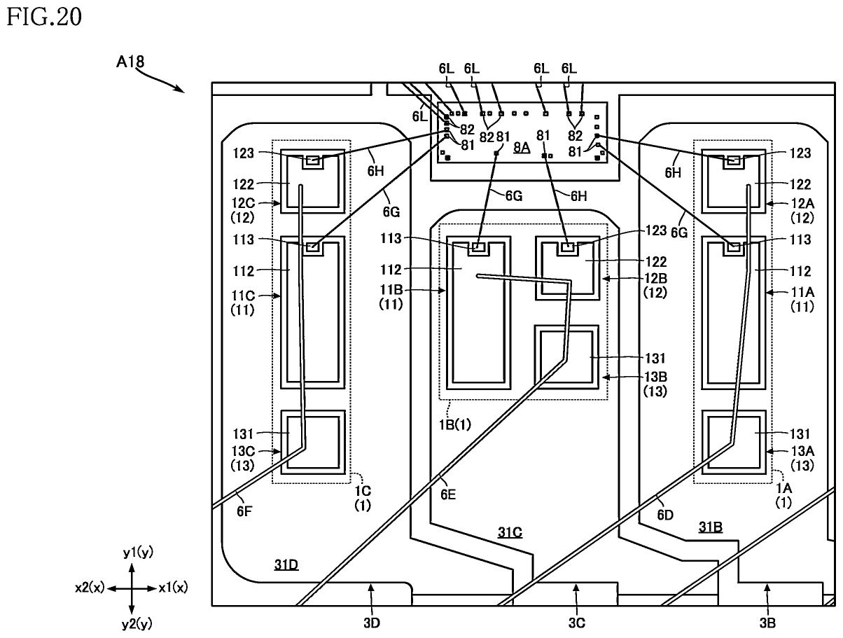

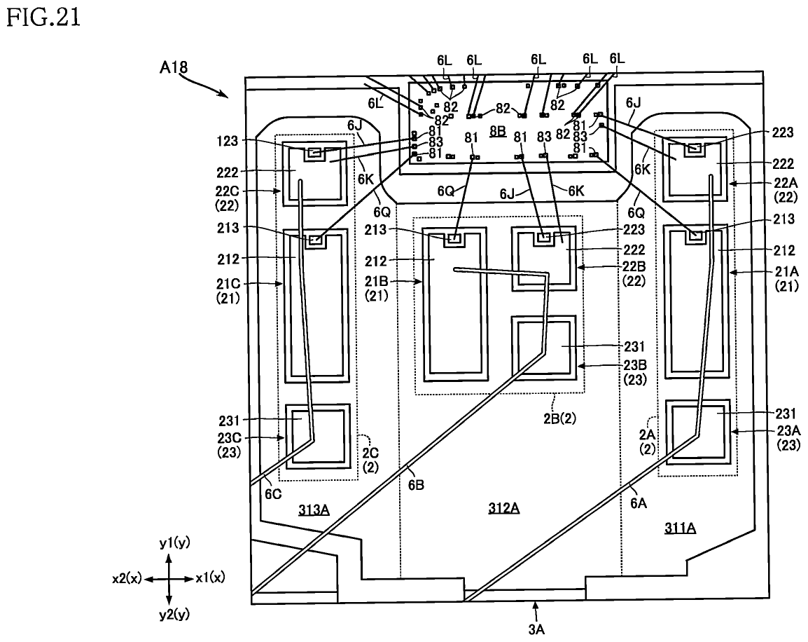

FIGS. 20 and 21 illustrate a semiconductor device A18 according to an eighth variation of the first embodiment. The semiconductor device A18 differs from the semiconductor device A1 as follows. The semiconductor device A18 has larger plan-view size of each first switching element 11 and each third switching element 21, as shown in FIGS. 20 and 21.

As explained above, each first switching element 11 contains Si as a semiconductor material and each second switching element 12 contains SiC as a semiconductor material. In this configuration, when each first switching element 11 and each second switching element 12 have the same plan-view size, the first switching element 11 may have higher on-resistance than the second switching element 12. In view of this, the semiconductor device A18 is designed to include each first switching element 11 with a larger plan-view size than each first switching element 11 of the semiconductor device A1, as shown in FIG. 20. This reduces the on-resistance of the first switching element 11 as small as a property value close to the on-resistance of the second switching element 12.

Similarly, each third switching element 21 contains Si as a semiconductor material and each fourth switching element 22 contains SiC as a semiconductor material. In this configuration, when each third switching element 21 and each fourth switching element 22 have the same plan-view size, the third switching element 21 may have higher on-resistance than the fourth switching element 22. In view of this, the semiconductor device A18 is designed to include each third switching element 21 with a larger plan-view size than each third switching element 21 of the semiconductor device A1, as shown in FIG. 21. This reduces the on-resistance of the third switching element 21 as small as a property value close to the on-resistance of the fourth switching element 22.

The semiconductor device A18 according to the present variation has the same advantages as the semiconductor device A1. As understood from the present variation, the semiconductor devices of the present disclosure are configured not only so that the plan-view size of the first switching element 11 may be the same as that of the second switching element 12 but also so that the plan-view sizes of them may be different. The same is applied to the third switching element 21 and the fourth switching element 22.

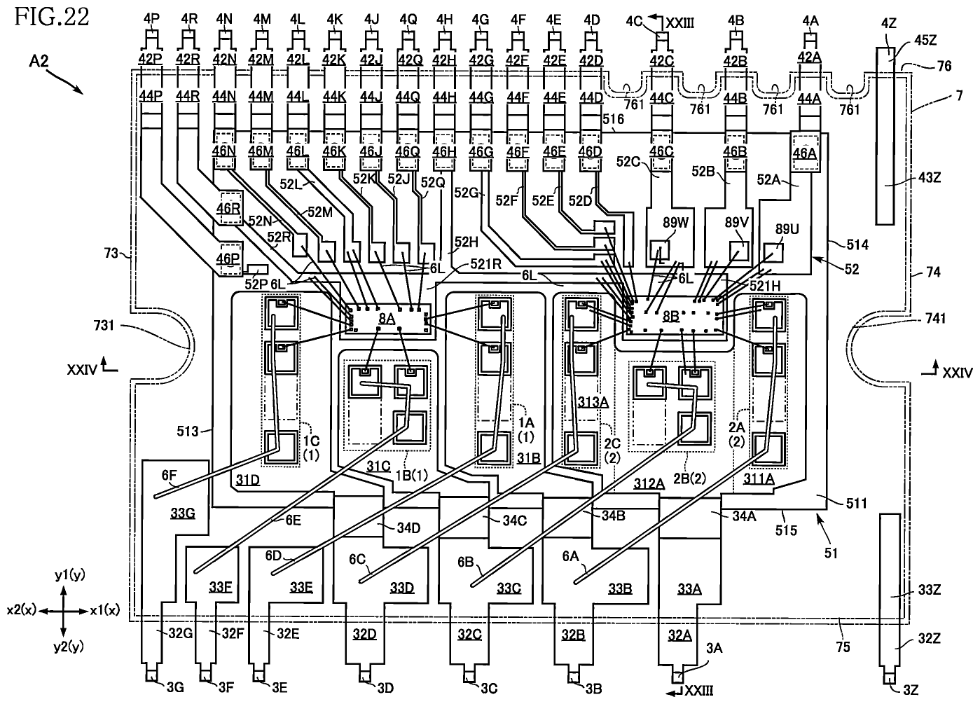

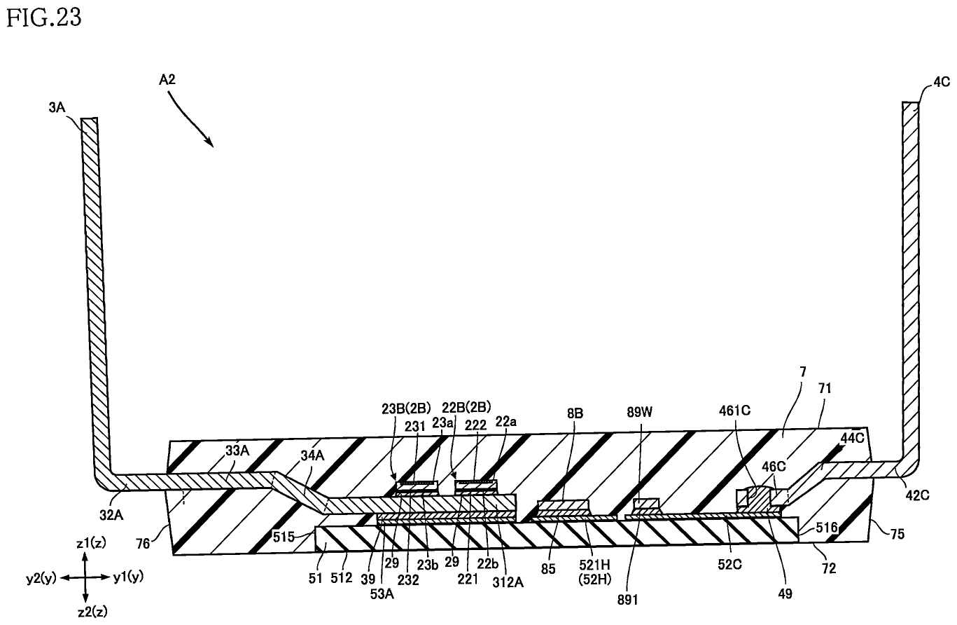

FIGS. 22 to 24 illustrate a semiconductor device A2 according to a second embodiment. As illustrated in these figures, the semiconductor device A2 includes a plurality of first switching parts 1, a plurality of second switching parts 2, a first control element 8A, a second control element 8B, a plurality of electronic components 89U, 89V, 89W, a plurality of leads 3A-3G, 3Z, a plurality of leads 4A-4H, 4J-4N, 4P-4R, a support substrate 51, a wiring pattern 52, a plurality of connection members 6, and a sealing member 7. In other words, the semiconductor device A2 differs from the semiconductor device A1 mainly in that it further includes the wiring pattern 52.

The wiring pattern 52 is provided on the first surface 511 of the support substrate 51. The wiring pattern 52 is made of a conductive material. The wiring pattern 52 is covered by the sealing member 7. The wiring pattern 52 includes a plurality of wiring parts 52A-52H, 52J-52N, 52P-52R and a plurality of bonding parts 53A-53D.

The wiring parts 52A-52H, 52J-52N, 52P-52R are each provided on the support substrate 51. In the present embodiment, the wiring parts 52A-52H, 52J-52N, 52P-52R is provided on the first surface 511 of the support substrate 51. Each of the wiring parts 52A-52H, 52J-52N, 52P-52R is made of a conductive material. The conductive material constituting each of the wiring parts 52A-52H, 52J-52N, 52P-52R is not specifically limited, including Ag, Cu, Au or the like. In the following, an example is explained that each of the wiring parts 52A-52H, 52J-52N, 52P-52R contains Ag. Each of the wiring parts 52A-52H, 52J-52N, 52P-52R may contain one of Cu and Au instead of Ag. Alternatively, each wiring part 52A-52H, 52J-52N, 52P-52R may contain Ag—Pt or Ag—Pd. Further, methods to form each of the wiring parts 52A-52H, 52J-52N, 52P-52R is not specifically limited, and they may be formed, for example, by printing a paste containing these metals and then firing it.

In the wiring parts 52A-52H, 52J-52N, 52P-52R, the wiring part 52H and the wiring part 52R is integrally formed, while the others are separated from each other. Unlike the example, the wiring part 52H and the wiring part 52R may be separated from each other.

The wiring part 52A, the wiring part 52B and the wiring part 52C are offset in the x1 side of the x direction with respect to the wiring part 52D, as shown in FIG. 22.

The wiring part 52A is bonded to the electronic component 89U and the wire 6L connected to the second control element 8B, as shown in FIG. 22. Further, the wiring part 52A is bonded to the lead 4A.

The wiring part 52B is bonded to the electronic component 89V and the wire 6L connected to the second control element 8B, as shown in FIG. 22. Further, the wiring part 52B is bonded to the lead 4B.

The wiring part 52C is bonded to the electronic component 89W and the wire 6L connected to the second control element 8B, as shown in FIG. 22. Further, the wiring part 52C is bonded to the lead 4C.

The wiring part 52D is offset in the x2 side of the x direction with respect to the wiring part 52C, as shown in FIG. 22. The wire 6L connected to the second control element 8B is bonded to the wiring part 52D. Further, the lead 4D is bonded to the wiring part 52D.

The wiring parts 52E, 52F, 52G are offset in the x2 side of the x direction with respect to the wiring part 52D, as shown in FIG. 22. The wire 6L connected to the second control element 8B is bonded to each of the wiring parts 52E, 52F, 52G. Each of the wiring parts 52E, 52F, 52G is bonded to the respective one of the leads 4E, 4F, 4G, as shown in FIG. 22.

The second control element 8B is mounted on the wiring part 52H. The lead 4H is bonded to the wiring part 52H. The wiring part 52H includes a pad part 521H, as shown in FIG. 22. The pad part 521H is a portion of the wiring part 52H to which the second control element 8B is bonded. The pad part 521H is rectangular in plan view. The pad part 521H includes a portion sandwiched by the two mounting parts 311A, 313A in the y direction, as shown in FIG. 22. The second control element 8B is disposed on the area in the pad part 521H between the two mounting parts 311A, 313A.

The first control element 8A is mounted on the wiring part 52R. The lead 4R is bonded to the wiring part 52R. The wiring part 52R includes a pad part 521R, as shown in FIG. 22. The pad part 521R is a portion of the wiring part 52R to which the first control element 8A is bonded. The pad part 521R is rectangular in plan view. The pad part 521R includes a portion sandwiched by the two mounting parts 31B, 31D in the y direction, as shown in FIG. 22. The first control element 8A is disposed on the area in the pad part 521R between the two mounting parts 31B, 31D.

The wiring parts 52Q, 52J, 52K, 52L, 52M, 52N are offset in the x2 side of the x direction with respect to the wiring part 52H, as shown in FIG. 22. The wire 6L connected to the first control element 8A is bonded to each of the wiring parts 52Q, 52J, 52K, 52L, 52M, 52N. Each of the wiring parts 52Q, 52J, 52K, 52L, 52M, 52N is bonded to the respective one of the leads 4Q, 4J, 4K, 4L, 4M, 4N, as shown in FIG. 22.

The lead 4P is bonded to the wiring part 52P, as shown in FIG. 22. In the present embodiment, the wire 6L is not bonded to the wiring part 52P.

The respective portions in the wiring parts 52A-52H, 52J-52N, 52P-52R to which the leads 4A-4H, 4J-4N, 4P-4R are bonded are disposed along the periphery of the support substrate 51 in plan view, as shown in FIG. 22.

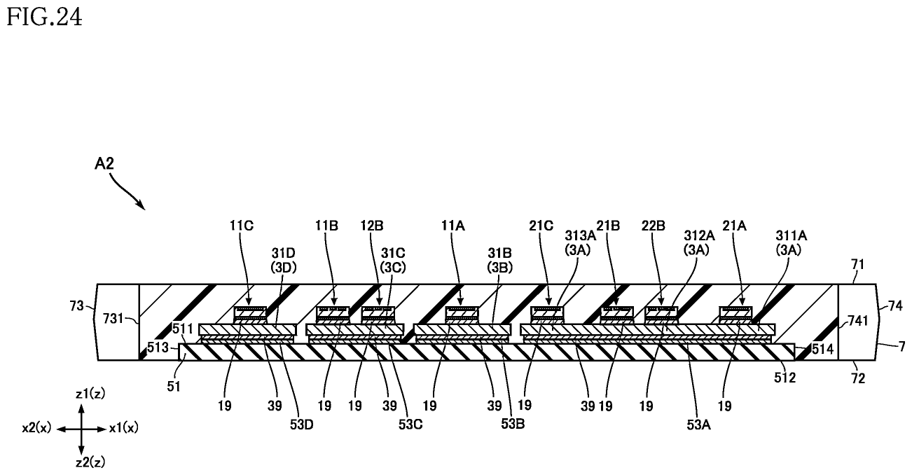

The bonding parts 53A-53D are each provided on the support substrate 51. Each bonding part 53A-53D is provided on the first surface 511 of the support substrate 51, as with the wiring parts 52A-52H, 52J-52N, 52P-52R, as shown in FIG. 24. As shown in FIG. 24, the bonding part 53A is disposed below (the z2 side of the z direction) the mounting parts 311A, 312A, 313A of the lead 3A, the bonding part 53B is disposed below (the z2 side of the z direction) the mounting part 31B of the lead 3B, the bonding part 53C is disposed below (the z2 side of the z direction) the mounting part 31C of the lead 3C, and the bonding part 53D is disposed below (the z2 side of the z direction) the mounting part 31D of the lead 3D. The constituent material of each bonding part 53A-53D is not specifically limited, and each bonding part 53A-53D is made of materials that can be bonded to the support substrate 51 and the respective lead 3A-3D. For example, each bonding part 53A-53D is made of a conductive material. The conductive material constituting each bonding part 53A-53D is not specifically limited, including Ag, Cu, Au or the like. Each bonding part 53A-53D contains the same conductive material as the material constituting each wiring part 52A-52H, 52J-52N, 52P-52R. Each bonding part 53A-53D may contain one of Cu and Au instead of Ag. Alternatively, each bonding part 53A-53D may contain Ag—Pt or Ag—Pd. Further, methods to form each bonding part 53A-53D is not specifically limited, and they may be formed, for example, by printing a paste containing these metals and then firing it, as with each bonding part 52A-52H, 52J-52N, 52P-52R. Each bonding part 53A-53D may not necessarily be conductive. The wiring pattern 52 may not necessarily include the bonding parts 53A-53D.

In the semiconductor device A2, the leads 4A-4H, 4J-4N, 4P-4R are bonded to the wiring pattern 52. The semiconductor device A2 further includes the lead 4z compared to the semiconductor device A1.

The leads 4A-4H, 4J-4N, 4P-4R are offset in the x2 side of the x direction with respect to the lead 4Z, as shown in FIG. 22. In the following, the lead 4A will be explained in detail, but the leads 4B-4H, 4J-4N, 4P-4R also include similar components. In this case, each component of the leads 4B-4H, 4J-4N, and 4P-4R corresponds to each component in the lead 4A whose letter “A” is replaced by “B”-“H”, “J”-“N”, and “P”-“R”, respectively.

The lead 4A includes a terminal part 42A, a connection part 44A and a bonding part 46A, as shown in FIG. 22. The terminal part 42A of the semiconductor device A2 is configured in the same way as the terminal part 42A of the semiconductor device A1. The connection part 44A connects the terminal part 42A and the bonding part 46A. The bonding part 46A is bonded to the wiring part 52A via a conductive bonding material 49. Similarly, the bonding part 46B (46C-46H, 46J-46N, 46P-46R) is bonded to the wiring part 52B (52C-52H, 52J-52N, 52P-52R) via the conductive bonding material 49. The conductive bonding material 49 include solder, metal paste material or sintered metal. The bonding part 46C is provided with a through-hole 461C, as shown in FIG. 19. Unlike this configuration, the bonding part 46C may not necessarily be provided with the through-hole 461C. The other bonding parts 46A, 46B, 46D-46H, 46J-46N, 46P-46R are also provided with the through-holes but may not require them.

The lead 4Z is offset in the x1 side of the x direction with respect to the lead 4A. The lead 4Z is not electrically connected to either the first switching parts 1, the second switching parts 2, the first control element 8A, or the second control element 8B. The lead 4Z includes a pad part 43Z and a projection part 45Z, as shown in FIG. 22. The pad part 43Z and the projection part 45Z are connected to each other.

The pad part 43Z is covered by the sealing member 7. The pad part 43Z does not overlap with the support substrate 51 in plan view, as shown in FIG. 22. The projection part 45Z extends from the pad part 43Z to the y1 side of the y direction, and protrudes from the sealing member 7, as shown in FIG. 22.

The semiconductor device A2 according to the present embodiment has the same advantages as the semiconductor device A1. For example, the semiconductor device A2 has a preferable structure for operating the switching elements (the first switching element 11 and the second switching element 12) as one first switching part 1, as with the semiconductor device A1.

The semiconductor device A2 includes the wiring pattern 52 on the first surface 511 of the support substrate 51. The wiring pattern 52 includes the wiring parts 52A-52H, 52J-52N, 52P-52R, which transmit the control signals for the first control element 8A and the second control element 8B to control the first switching parts 1 and the second switching parts 2 (e.g. the above-described first input signal and the above-described second input signal) and constitute transmission paths for the signals. The wiring parts 52A-52H, 52J-52N, 52P-52R are formed, for example, by printing pastes containing Ag and then firing them. Such a configuration allows for miniaturization and densification of transmission paths compared to the configuration that a metal lead flame constitute the transmission paths. Therefore, the semiconductor device A2 achieves a higher level of integration.

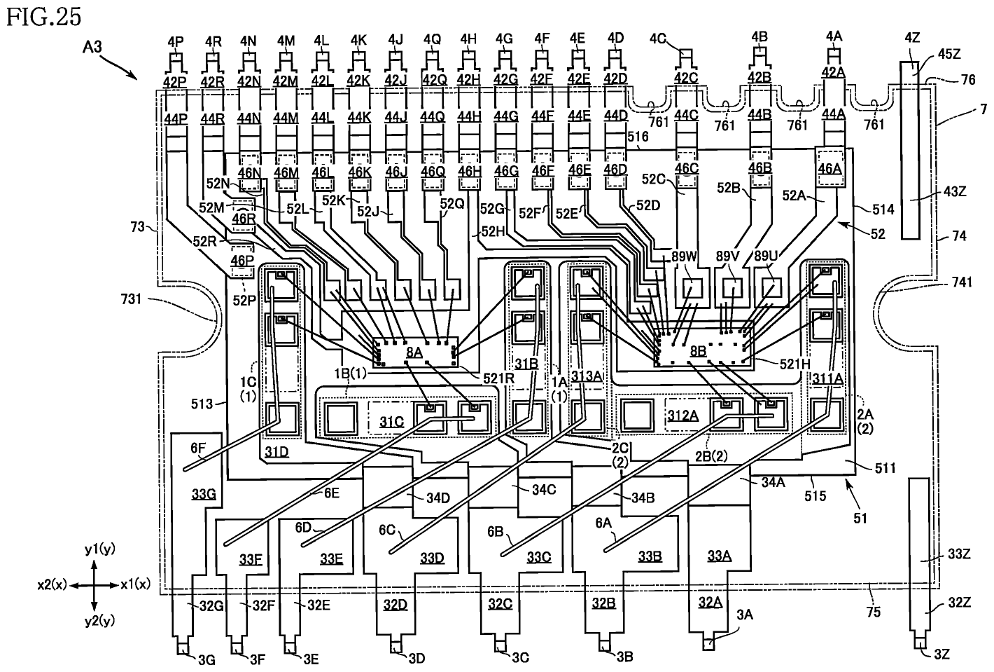

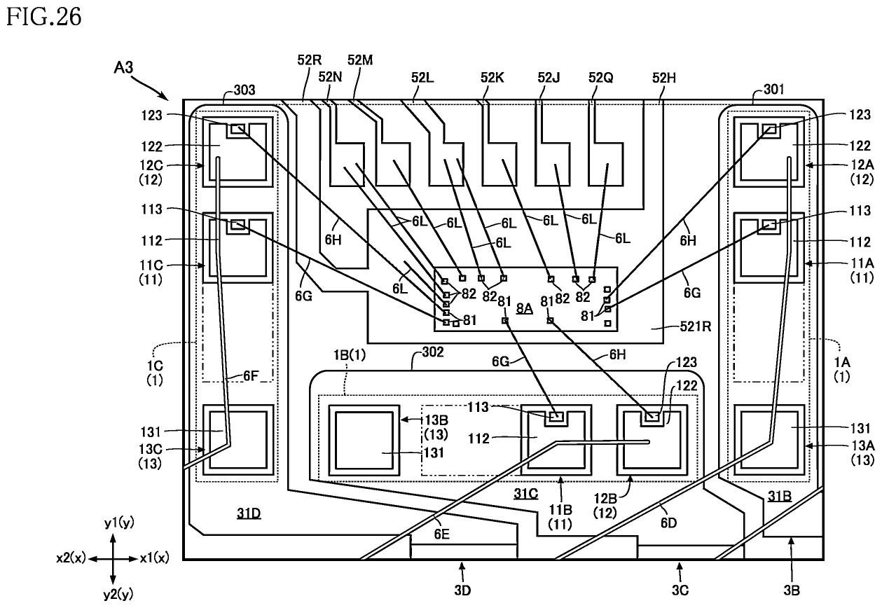

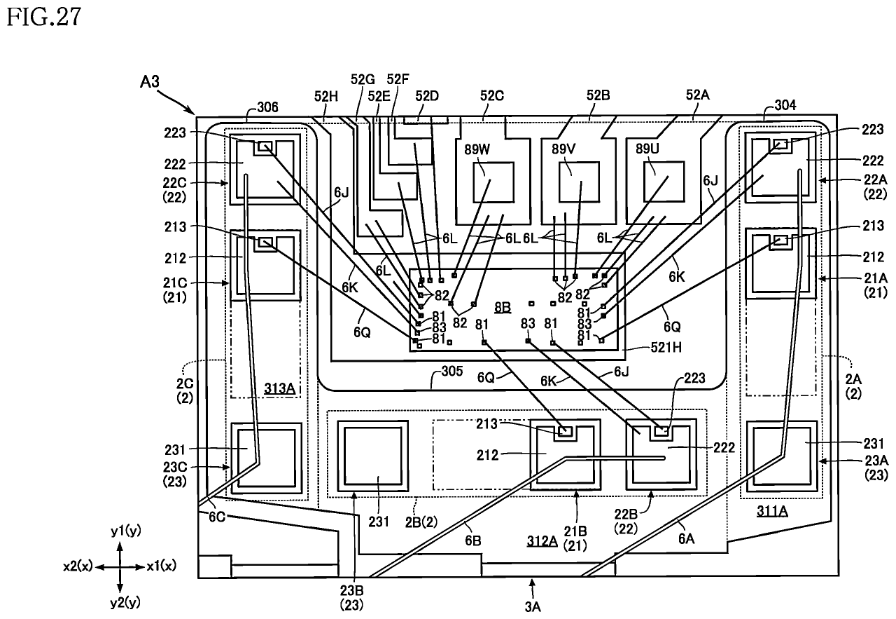

FIGS. 25-27 illustrate a semiconductor device A3 according to a third embodiment. The semiconductor device A3 differs from the semiconductor device A2 as follows. They differ in the arrangement of the first switching element 11B, the second switching element 12B and the first protective element 13B in the second arm 1B, as shown in FIGS. 25 and 26. Further, they differ in the arrangement of the third switching element 21B, the fourth switching element 22B and the second protective element 23B in the fifth arm 2B, as shown in FIGS. 25 and 27.

In the semiconductor device A3, the first switching element 11B, the second switching element 12B and the first protective element 13B are arranged along the x direction, as shown in FIG. 26. With such a configuration, the edge 302 of the mounting part 31C is offset further in the y2 side of the y direction with respect to the edge 301 of the mounting part 31B and the edge 303 of the mounting part 31D, as shown in FIG. 26.

Similarly, the semiconductor device A3 includes the third switching element 21B, the fourth switching element 22B and the second protective element 23B arranged along the x direction, as shown in FIG. 27. With such a configuration, the edge 305 of the mounting part 312A is offset further in the y2 side of the y direction with respect to the edge 304 of the mounting part 311A and the edge 306 of the mounting part 313A, as shown in FIG. 27. This results in that not only the second control element 8B but also the electronic components 89U, 89V, 89W being disposed between the two mounting parts 311A, 313A in the y direction, as shown in FIG. 27.

The semiconductor device A3 according to the present embodiment has the same advantages as the semiconductor device A1. For example, the semiconductor device A3 has a preferable structure for operating the switching elements (the first switching element 11 and the second switching element 12) as one first switching part 1, as with the semiconductor device A1. Further, in the semiconductor device A3, as shown in FIG. 27, not only the second control element 8B but also the electronic components 89U, 89V, 89W being disposed between the two mounting parts 311A, 313A in the y direction, which enables the size in the y direction to be further reduced.

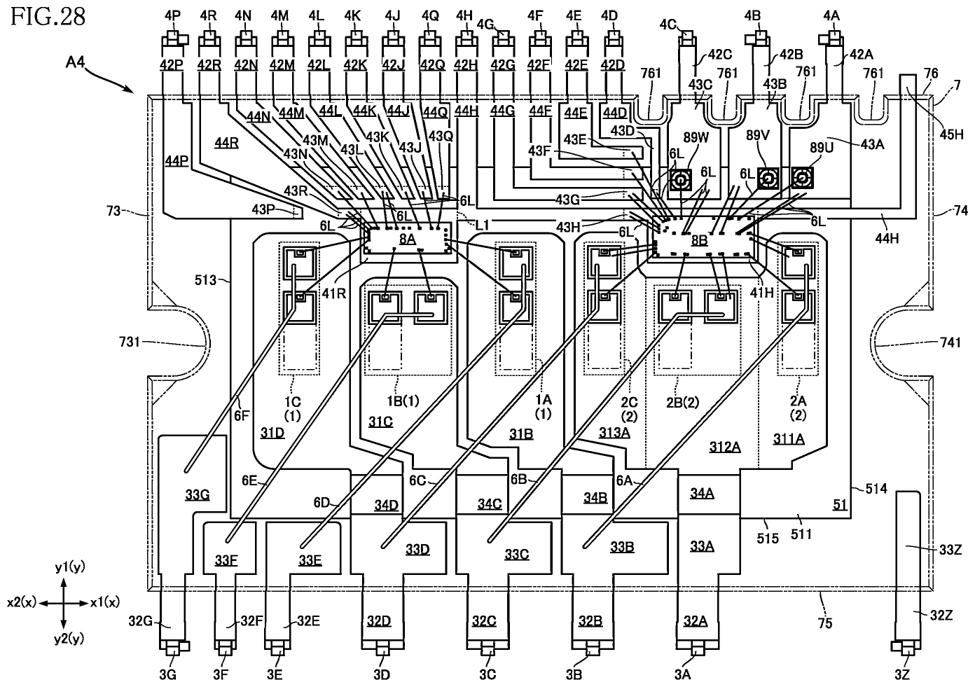

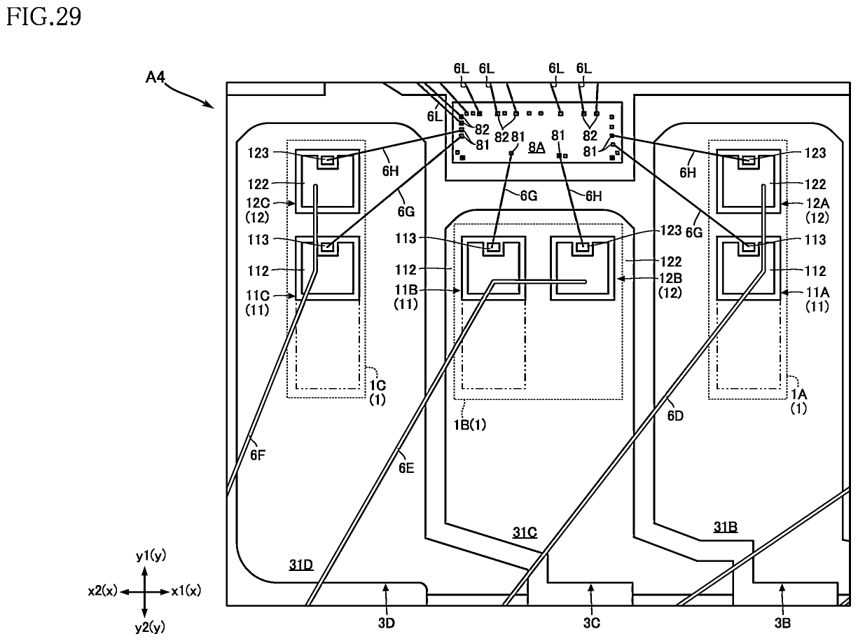

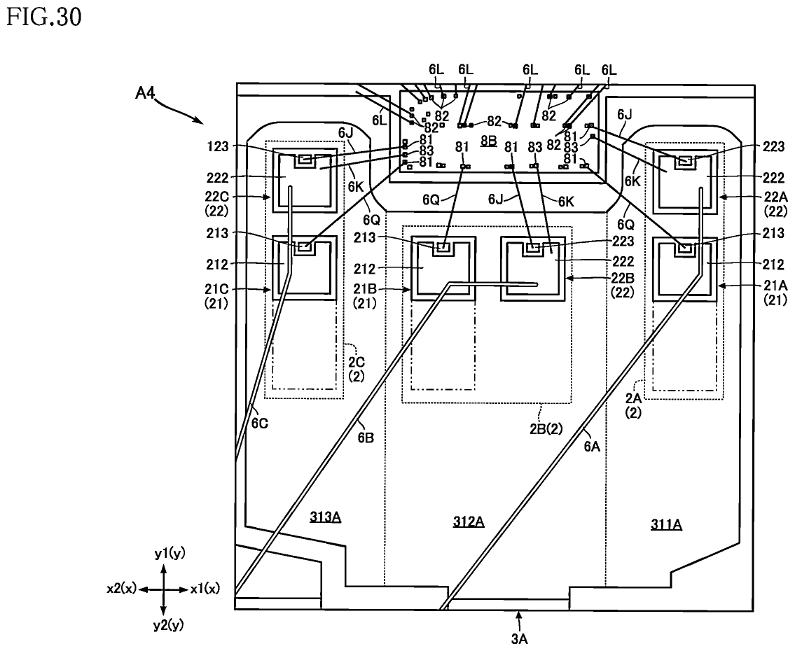

FIGS. 28-31 illustrate a semiconductor device A4 according to a fourth embodiment. The semiconductor device A4 differs from the semiconductor device A1 as follows. The semiconductor device A4 does not include the first protective element 13 in each first switching part 1, as shown in FIGS. 28, 29 and 31. Further, the semiconductor device A4 does not include the second protective element 23 in each second switching part 2, as shown in FIGS. 28, 30 and 31.

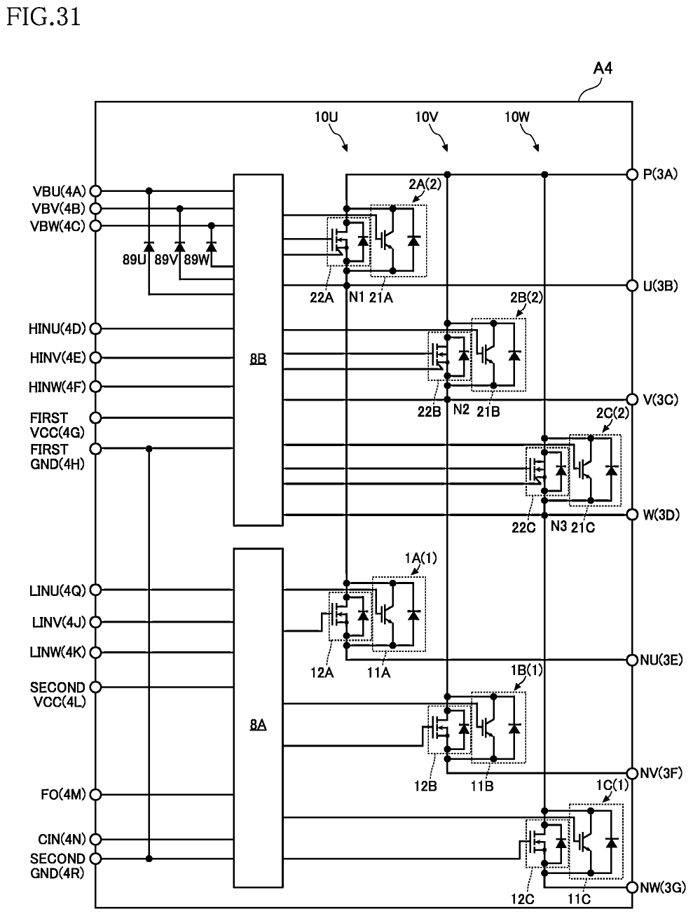

The first switching element 11 in each first switching part 1 is a reverse-conducting IGBT, which includes a switching function part and a diode function part, as shown in FIG. 31. The switching function part operates as an IGBT, and the diode function part operates as a free-wheeling diode. In other words, each first switching element 11 of the present embodiment embeds the diode function part (the free-wheeling diode). For example, each first switching element 11 is a single chip incorporating the first switching element 11 and the first protective element 13 in the semiconductor device A1 and embeds the diode function part (the free-wheeling diode). In each first switching element 11, the switching function part and the diode function part are electrically connected in anti-parallel, as shown in FIG. 31.

The third switching element 21 in each second switching part 2 is a reverse-conducting IGBT, which includes a switching function part and a diode function part, as shown in FIG. 31. The switching function part operates as an IGBT, and the diode function part operates as a free-wheeling diode. In other words, each third switching element 21 of the present embodiment embeds the diode function part (the free-wheeling diode). For example, each third switching element 21 is a single chip incorporating the third switching element 21 and the second protective element 23 of the semiconductor device A1. In each third switching element 21, the switching function part and the diode function part are electrically connected in anti-parallel, as shown in FIG. 31.

The semiconductor device A4 according to the present embodiment has the same advantages as the semiconductor device A1. For example, the semiconductor device A4 has a preferable structure for operating the switching elements (the first switching element 11 and the second switching element 12) as one first switching part 1, as with the semiconductor device A1.

The above-described semiconductor devices A2-A4 may be configured in the same manner as each variation of the semiconductor device A1 in any way as long as the variation is technically compatible. For example, in FIGS. 22 and 25-30, each first switching element 11 and each third switching element 21 with enlarged plan-view sizes, as with the eighth variation of the first embodiment, are each indicated as imaginary lines

In the above-described embodiments and variations, it is also possible to further reduce surplus portions in each mounting part 311A, 312A, 313A, 31B, 31C, 31D where neither the first switching elements 11, the second switching elements 12, the first protective elements 13, the third switching elements 21, the fourth switching elements 22 nor the second protective elements 23 are mounted. Reducing surplus portions is preferable for minimizing the plan-view size of the semiconductor devices.

The present disclosure is not limited to the foregoing embodiments. The specific configuration of each part of the semiconductor device according to the present disclosure can be varied in design in many ways. The present disclosure may include the embodiments described in the following clauses.

### Clause 1.

A semiconductor device comprising:
a plurality of first switching parts each including a first switching element and a second switching element;
a first control element to input a first drive signal to the first switching element and the second switching element of each first switching part;
at least one lead on which the first switching element and the second switching element of each first switching part are mounted;
a plurality of first connection members each connected to the first control element and the first switching element of each first switching part; and
a plurality of second connection members each connected to the first control element and the second switching element of each first switching part,
wherein, in the plurality of first switching parts, the first switching element and the second switching element are electrically connected in parallel to each other and are of different types, and
the first switching element and the second switching element of each first switching part are disposed around the first control element as viewed in a thickness direction.

### Clause 2.

The semiconductor device according to clause 1, wherein the first switching element of each first switching part is an IGBT, and
the second switching element of each first switching part is a MOSFET.

### Clause 3.

The semiconductor device according to clause 1 or 2, wherein each first switching part includes a diode function part.

### Clause 4.

The semiconductor device according to clause 3, wherein, the diode function part is embedded by the first switching element in each first switching part.

### Clause 5.

The semiconductor device according to clause 3, wherein, in each first switching part, the diode function part is composed of an element different from each of the first switching element and the second switching element.

### Clause 6.

The semiconductor device according to any one of clauses 1 to 5, wherein the plurality of first switching parts include a first arm, a second arm and a third arm each including the first switching element and the second switching element,
the first arm, the second arm and the third arm are arranged along a first direction orthogonal to the thickness direction, and
the second arm is located between the first arm and the third arm in the first direction.

### Clause 7.

The semiconductor device according to clause 6, wherein, in each of the first arm and the third arm, the first switching element and the second switching element are arranged along a second direction orthogonal to the thickness direction and the first direction, and
in the second arm, the first switching element and the second switching element are arranged along the first direction.

### Clause 8.

The semiconductor device according to clause 7, wherein the at least one lead includes a first mounting part, a second mounting part and a third mounting part,
the first switching element and the second switching element of the first arm are mounted on the first mounting part,
the first switching element and the second switching element of the second arm are mounted on the second mounting part, and
the first switching element and the second switching element of the third arm are mounted on the third mounting part.

### Clause 9.

The semiconductor device according to clause 8, wherein the first control element is offset in one side of the second direction with respect to an edge of the second mounting part in the one side of the second direction, and
the edge of the second mounting part in the one side of the second direction is offset in other side of the second direction with respect to an edge of the first mounting part in the one side of the second direction and an edge of the third mounting part in the one side of the second direction.

### Clause 10.

The semiconductor device according to clause 9, wherein an edge of the first mounting part in the other side of the second direction is located between the edge of the second mounting part in the one side of the second direction and each of the edge of the first mounting part in the one side of the second direction and the edge of the third mounting part in the one side of the second direction.

### Clause 11.

The semiconductor device according to any one of clauses 8 to 10, wherein the at least one lead includes a first lead, a second lead and a third lead that are separated from each other,
the first lead includes the first mounting part,
the second lead includes the second mounting part,
the third lead includes the third mounting part.

### Clause 12.

The semiconductor device according to any one of clauses 6 to 11, further comprising:
a plurality of second switching parts each including a third switching element and a fourth switching element; and
a second control element to input a second drive signal to the third switching element and the fourth switching element of each second switching part.

### Clause 13.

The semiconductor device according to clause 12, wherein the plurality of second switching parts include a fourth arm, a fifth arm and a sixth arm each including the third switching element and the fourth switching element,
the fourth arm, the fifth arm and the sixth arm are arranged along the first direction orthogonal to the thickness direction, and
the fifth arm is located between the fourth arm and the sixth arm in the first direction.

### Clause 14.

The semiconductor device according to clause 13, wherein, in each of the fourth arm and the sixth arm, the third switching element and the fourth switching element are arranged along the second direction orthogonal to the thickness direction and the first direction, and
in the fifth arm, the third switching element and the fourth switching element are arranged along the first direction.

### Clause 15.

The semiconductor device according to clause 14, wherein the at least one lead includes a fourth mounting part, a fifth mounting part and a sixth mounting part,
the third switching element and the fourth switching element of the fourth arm are mounted on the fourth mounting part,
the third switching element and the fourth switching element of the fifth arm are mounted on the fifth mounting part, and
the third switching element and the fourth switching element of the sixth arm are mounted on the sixth mounting part.

### Clause 16.

The semiconductor device according to clause 15, wherein the at least one lead includes a fourth lead, and
the fourth lead includes the fourth mounting part, the fifth mounting part and the sixth mounting part.

### Clause 17.

The semiconductor device according to any one of clauses 13 to 16, wherein the first arm as a lower arm and the fourth arm as an upper arm are electrically connected in series to configure a first phase in a three-phase alternating-current circuit,
the second arm as a lower arm and the fifth arm as an upper arm are electrically connected in series to configure a second phase in the three-phase alternating-current circuit, and
the third arm as a lower arm and the sixth arm as an upper arm are electrically connected in series to configure a third phase in the three-phase alternating-current circuit.

REFERENCE NUMERALS
A1, A11-A18, A2, A3, A4: Semiconductor device
10U: First phase 10V: Second phase
10W: Third phase 1: First switching part
1A: First arm 1B: Second arm 1C: Third arm
11, 11A, 11B, 11C: First switching element
11a: Element obverse surface 11b: Element reverse surface
111, 112, 113: Electrode
12, 12A, 12B, 12C: Second switching element
12a: Element obverse surface 12b: Element reverse surface
121, 122, 123: Electrode
13, 13A, 13B, 13C: First protective element
13a: Element obverse surface 13b: Element reverse surface
131, 132, 133: Electrode 19: Conductive bonding material
2: Second switching part 2A: Fourth arm
2B: Fifth arm 2C: Sixth arm
21, 21A, 21B, 21C: Third switching element
21a: Element obverse surface 21b: Element reverse surface
211, 212, 213: Electrode
22, 22A, 22B, 22C: Fourth switching element
22a: Element obverse surface 22b: Element reverse surface
221, 222, 223: Electrode
23, 23A, 23B, 23C: Second protective element
23a: Element obverse surface 23b: Element reverse surface
231, 232: Electrode 29: Conductive bonding material
3A-3G, 3Z: Lead 301-306: Edge
311A, 312A, 313A, 31B-31D: Mounting part
32A-32G, 32Z: Terminal part 33A-33G, 33Z: Pad part
34A-34D: Connection part 39: Bonding material
4A-4H, 4J-4N, 4P-4R, 4Z: Lead 41H, 41R: Mounting part
42A-42H, 42J-42N, 42P-42R: Terminal part
43A-43H, 43J-43N, 43P-43R, 43Z: Pad part
44A-44H, 44J-44N, 44P-44R: Connection part
45H: Projecting part 45Z: Projecting part
46A-46H, 46J-46N, 46P-46R: Bonding part
461C: Through-hole 49: Conductive bonding material
51: Support substrate 511: First face
512: Second face 513: Third face
514: Fourth face 515: Fifth face
516: Sixth face 52: Wiring pattern
52A-52H, 52J-52N, 52P-52R: Wiring part
521H, 521R: Pad part 53A-53D: Bonding part
6: Connection member 6A-6H, 6J-6N, 6P-6R: Wire
7: Sealing member 71: Resin obverse surface
72: Resin reverse surface 73-76: Resin side face
731, 741, 761: Recess 8A: First control element
8B: Second control element 81, 82, 83: Electrode
85: Bonding material 89U, 89V, 89W: Electronic component
891: Conductive bonding material

1. A semiconductor device comprising:
a plurality of first switching parts each including a first switching element and a second switching element;
a first control element to input a first drive signal to the first switching element and the second switching element of each first switching part;
at least one lead on which the first switching element and the second switching element of each first switching part are mounted;
a plurality of first connection members each connected to the first control element and the first switching element of each first switching part; and
a plurality of second connection members each connected to the first control element and the second switching element of each first switching part,
wherein, in the plurality of first switching parts, the first switching element and the second switching element are electrically connected in parallel to each other and are of different types, and
the first switching element and the second switching element of each first switching part are disposed around the first control element as viewed in a thickness direction.

2. The semiconductor device according to claim 1, wherein the first switching element of each first switching part is an IGBT, and
the second switching element of each first switching part is a MOSFET.

3. The semiconductor device according to claim 1, wherein each first switching part includes a diode function part.

4. The semiconductor device according to claim 3, wherein the diode function part is embedded by the first switching element in each first switching part.

5. The semiconductor device according to claim 3, wherein, in each first switching part, the diode function part is composed of an element different from each first switching element and the second switching element.

6. The semiconductor device according to claim 1, wherein the plurality of first switching parts include a first arm, a second arm and a third arm each including the first switching element and the second switching element,
the first arm, the second arm and the third arm are arranged along a first direction orthogonal to the thickness direction, and
the second arm is located between the first arm and the third arm in the first direction.

7. The semiconductor device according to claim 6, wherein, in each of the first arm and the third arm, the first switching element and the second switching element are arranged along a second direction orthogonal to the thickness direction and the first direction, and
in the second arm, the first switching element and the second switching element are arranged along the first direction.

8. The semiconductor device according to claim 7, wherein the at least one lead includes a first mounting part, a second mounting part and a third mounting part,
the first switching element and the second switching element of the first arm are mounted on the first mounting part,
the first switching element and the second switching element of the second arm are mounted on the second mounting part, and
the first switching element and the second switching element of the third arm are mounted on the third mounting part.

9. The semiconductor device according to claim 8, wherein the first control element is offset in one side of the second direction with respect to an edge of the second mounting part in the one side of the second direction, and
the edge of the second mounting part in the one side of the second direction is offset in other side of the second direction with respect to an edge of the first mounting part in the one side of the second direction and an edge of the third mounting part in the one side of the second direction.

10. The semiconductor device according to claim 9, wherein an edge of the first mounting part in the other side of the second direction is located between the edge of the second mounting part in the one side of the second direction and each of the edge of the first mounting part in the one side of the second direction and the edge of the third mounting part in the one side of the second direction.

11. The semiconductor device according to claim 8, wherein the at least one lead includes a first lead, a second lead and a third lead that are separated from each other,
the first lead includes the first mounting part,
the second lead includes the second mounting part,
the third lead includes the third mounting part.

12. The semiconductor device according to claim 6, further comprising:
a plurality of second switching parts each including a third switching element and a fourth switching element; and
a second control element to input a second drive signal to the third switching element and the fourth switching element of each second switching part.

13. The semiconductor device according to claim 12, wherein the plurality of second switching parts include a fourth arm, a fifth arm and a sixth arm each including the third switching element and the fourth switching element,
the fourth arm, the fifth arm and the sixth arm are arranged along the first direction orthogonal to the thickness direction, and
the fifth arm is located between the fourth arm and the sixth arm in the first direction.

14. The semiconductor device according to claim 13, wherein, in each of the fourth arm and the sixth arm, the third switching element and the fourth switching element are arranged along a second direction orthogonal to the thickness direction and the first direction, and
in the fifth arm, the third switching element and the fourth switching element are arranged along the first direction.

15. The semiconductor device according to claim 14, wherein the at least one lead includes a fourth mounting part, a fifth mounting part and a sixth mounting part,
the third switching element and the fourth switching element of the fourth arm are mounted on the fourth mounting part,
the third switching element and the fourth switching element of the fifth arm are mounted on the fifth mounting part, and
the third switching element and the fourth switching element of the sixth arm are mounted on the sixth mounting part.

16. The semiconductor device according to claim 15, wherein the at least one lead includes a fourth lead, and
the fourth lead includes the fourth mounting part, the fifth mounting part and the sixth mounting part.

17. The semiconductor device according to claim 13, wherein the first arm as a lower arm and the fourth arm as an upper arm are electrically connected in series to configure a first phase in a three-phase alternating-current circuit,
the second arm as a lower arm and the fifth arm as an upper arm are electrically connected in series to configure a second phase in the three-phase alternating-current circuit, and
the third arm as a lower arm and the sixth arm as an upper arm are electrically connected in series to configure a third phase in the three-phase alternating-current circuit.
